(19) United States
(12) Patent Application Publication
(10) Pub. No.: US 2010/0276733 A1
(43) Pub. Date: Nov. 4, 2010

(54) Solid-state circuit device

(76) Inventor: Choa H. Li, West Orange, NJ (US)

Correspondence Address: Chou H. Li, 1 Oak Bend Road, West Orange, NJ, 07052, US

(21) Appl. No.: 11/546,750

(22) Filed: Oct. 13, 2006

Related U.S. Application Data
(63) Continuation-in-part of application No. 10/630,115, filed on Jul. 29, 2003, now Pat. No. 7,118,942.
Application No. 10/630,115 is a continuation-in-part of application No. 09/670,571, filed on Sep. 27, 2000, now Pat. No. 6,599,781.
Application No. 09/670,571 is a continuation-in-part of application No. 09/670,874, filed on Sep. 27, 2000, now Pat. No. 6,784,515.

(51) Int. Cl. H01L 27/06; H01L 27/02; H01L 29/66

(52) U.S. Cl. 257/252; 257/499; 257/414; 257/E29.166; 257/E27.009; 257/E27.011

(57) ABSTRACT

A commercially mass-produced ultra-miniaturized solid state system for using an ultraminiaturized atomic or molecular integrated circuit with gigabit memory and picosecond speed to automatically perform self-optimizing tasks selected from the group consisting of searching, tracking, teletraining, telelearning, telemedical diagnosis or treatment, and implanting knowledge or skill

### CROSS REFERENCE TO RELATED APPLICATIONS

This application is a continuation-in-part of application Ser. No. 10/630,115 filed Jul. 29, 2003 now allowed. The 630,115 application is a continuation-in-part of application Ser. No. 09/670,571 filed on Sep. 27, 2000 now U.S. Pat. No. 6,599,781; and also of application Ser. No. 09/670,874 filed on Sep. 27, 2000 now U.S. Pat. No. 6,784,515. I hereby incorporate all the above-cited patents and patent applications into this application.

### BACKGROUND OF THE INVENTION

1. Field of the Invention

The invention relates to methods of making atomic integrated circuit devices and more particularly to methods of making improved miniaturized atomic semiconductor integrated circuit devices.

2. Background of the Invention

Shockley, Bardeen, and Brattain invented the transistor around 1950 and started the modern electronics age. Kilby and Noyce next combined active and passive components on a single chip and invented the integrated circuit. But even only several components were combined, the yield was low. Fairchild's Isoplanar technology (FIG. 1) made possible medium-scale and larger-scale integrated circuits in 1972 according to Peltzer's U.S. Pat. No. 3,648,125. Simultaneously, other similar dielectric isolation processes, such as Kooi's LOCOS (i.e., local oxide isolation technology) of Philip and Magdos's oxide-recessed technology of IBM, were also widely used.

In a 1976 four-party Interference No. 98,426, Li's application Ser. No. 154,300 on round-bottomed isolating oxide groove was considered as the “Senior-most Inventor” having an effective filing date of Sep. 23, 1986 among Fairchild's Peltzer, Philip's Kooi, and IBM's Magdo and Magdo.

According to Peltzer's patent, the Fairchild's Isoplanar device 40 as typified by FIG. 1 in his '125 patent has a n-type epitaxial silicon layer 42 formed on a p-type substrate 41. Oxide isolating regions, e.g., 44a, 44b, 44c, and 44d are used to isolate the different components. Each of these oxide isolating regions has a wide central flat bottom occupying much of the chip real estate and producing unnecessarily larger devices.

Li's round-bottomed isolating oxide groove 21 of FIG. 2 was conceived on Sep. 23, 1968 as shown in his U.S. Pat. No. 3,585,714, column 12, lines 72-75. In the application Ser. No. 154,300, this device is shown to improve device leakage current and breakdown voltage. Also, the groove bottom G of zero width eliminates the wasted chip real estate of all other previously existing devices of, e.g., Isoplanar, LOCOS, and oxide-recessed types.

The groove bottom G must have zero bottom width. This is because the contact between a rigid quartz (SiO₂) cylinder or round rod 21 of the FIG. 2 laid on top of a highly polished silicon (Si) substrate 22 is a line of zero width.

To achieve the beneficial, proximity rounding effect of the groove bottom on the critical PN junction, the groove bottom G must also be microscopically close to the bottom of the PN junction. Li's U.S. Pat. No. 3,585,714 (U.S. application Ser. No. 761,646) and patent application Ser. No. 154,300 specifically and repeatedly disclose the preferred vertical groove depths as including: (1) within one micron; (2) within 0.1 microns; (3) and nearly zero microns.

The '714 patent discloses the h=1 um (micron=10⁻⁴ cm) feature at least four times, i.e., at column (col.) 5, lines 69-70 and 70, col. 4, line 70, and col. 6, line 45; and the h=0 microns feature at least five times at col. 6, line 43, and for infinite surface expansion at h=0 at col. 6, lines 43, 41-43 and lines 35-36, col. 8, lines 61-62, and col. 9, lines 61-64. A 1981 PTO Board decision 456-32 dated Jun. 17, 1981 on page 8, lines 21-25 gives additional twenty 0.1-micron features, because Li disclosed “a range of zero to 1.0 microns as the distance between the PN junction and the bottom of the groove. Based upon this disclosure, the artisan would have found it obvious to select a distance within the range specified”, such as 0.1 microns. See the “Other References at the end of this specification before the claims). Hence, the '714 patent discloses five h=0, four h=1.0 um, and twenty (5×4=20) h=0.1 um, for a total of twenty-nine groove depth h= or <1 micron times.

The 154,300 patent application discloses the h=0 um three times on page 5, line 7 and lines 5-7 and FIG. 1 at Point G; each of the h=1 um and h=2 um feature once on page 8, line 22, and the h=5 um feature once 5, line 10, as the 1981 PTO Board Decision dated Aug. 12, 1981 clearly pointed out on page 3, lines 14-16. According to the same reasoning given on the '714 patent, this '300 application discloses three h=0, nine times h=0.1 um, and seven times h=1 um, for a total of nineteen disclosures of h= or <1 micron.

This unique rounding feature produces smaller devices, but also gives rounded PN junction region peripheral surface minimizing contamination by micron-size or even atomic particles thereby increasing yield. See FIG. 2. The smaller the device size, the more critical this yield factor.

Specifically, the rounded groove 21 produces a curved, exposed peripheral junction surface preventing contamination by rubbing contacts with dust particles or processing equipment. Such contacts form, e.g., metallic shorting paths and drastically reduce the device yield by increasing leakage current and decreasing breakdown voltage. Li's U.S. Pat. No. 3,430,109 discloses at column 5, lines 15-20 that for a one-micron (thick) PN junction region, a single-atomic gold chain one-micron long contains 3,903 gold atoms giving a leakage current of 0.15 ma at 50 volts thereby destroying the device. A single 1-micron gold particle could possibly destroy 7.977×10⁶ devices.

Knowing the problem, the solution is very simple yet critical—groove rounding and the cleaning room. Modern devices have much thinner junction regions so that the same 1-micron gold particle could now destroy over 1 billion, devices!

In the patent application Ser. No. 154,300, the device of FIG. 2 is made by thermally growing an oxide groove, band, or material region 21 transversely into a p-type silicon substrate 22. This is followed by oxide-guided, maskless diffusion of n-type dopants from the top surface 23 to give the top n-type silicon layer 24 and the new PN junction region 25. The rounded bottom G has a zero bottom width.

FIG. 2 shows partial vertical cross-section of Li's prior-art isoplanar device with a round-bottomed and sloping sided isolating groove of zero bottom width, achieving the maximum device miniaturization by the diffusion process.

All these devices can still be improved, both in performance and device size. While retaining the rounded bottom feature, the oxide isolating regions or field layers in this present invention are further narrowed down to even one or two atomic layers occupying the minimum chip real estate. The present invention thus provides still better and further miniaturized solid-state integrated circuits (IC) in general and semiconductor integrated circuits in particular.

Specifically, this invention will address the following issues:

1) improving the critical gate layer material and structure;

2) reducing the insulating field oxide region size by orders of magnitude from microns to angstroms;

3) making the entire device more resistant to temperature, stress, impact, vibration, and high-gravity (G) forces due to rapid accelerations and decelerations;

4) simplifying device material inventories and manufacturing process;

5) providing a new type of high-performance flexible circuits;

6) designing 1-D (one-dimensional), 2-D, and 3-D atomic or molecular diode or transistor arrays of IC especially useful for supercomputers and electro-optical telecommunications; and

7) producing new atomic or molecular IC operating selectively in a single-electron, single-hole, single-carrier, single-particle, or single-photon mode.

The devices of the invention may use different solid-state or semiconductor materials including Si, Ge, Si—Ge, GaAs, SiC, InAs, InP, InAlP, superconductor, and diamond, and periodic group III-V or II-VI semiconductors. In this invention, Si semiconductor materials are exclusively used by way of illustration. Also, metal-oxide-semiconductor (MOS) or, in general, conductor-insulator-semiconductor (CIS) devices are used exclusively as examples in this specification. Other types of solid-state devices in general and semiconductor devices in particular are also useful. Specifically, electro optical, superconductor, magnetic, ferro electric memory, electrooptomagnetic, and other solid-state devices can also be designed according to principles of this invention.

The “heart” of the transistor is the gate dielectric layer, where most electronic actions and the associated heating or degradations occur. The gate oxide dielectric is the smallest but a most critical feature of the transistor. It lies between the transistor's gate electrode, which turns current flow, and the silicon channel through which the current flows. The gate oxide insulates and protects the channel from the gate electrode preventing short circuits. Shrinking this gate oxide layer allows more current out of the switch with less voltage.

More than any other part of the structure, this layer determines the device performance and reliability. Many think that this insulating layer would be the limiting factor for producing increasingly smaller chips.

The thickness of gate oxides is the subject of intense research and development. Bell Laboratory scientists have created a 5-atom silicon dioxide layer that included a 1-atom transition layer between this layer and the substrate. A rapid thermal oxidation technique was used using pure oxygen at 1,000° C. for 10 seconds. Oxides less than 6 angstroms or 3 atoms have been made, but the leakage current was not manageable. Additional reliability issues included adhesion loss, texture, thermally or mechanically induced cracking, moisture adsorption, step coverage, and time-dependent behavior on, e.g., thermal conductivity, and breakdown voltage. The reduced mechanical strength is critical in both packaging and processing such as during chemical-mechanical polishing.

Traditionally, the gate dielectric has been—and it still is—a thermally grown layer of silicon dioxide (SiO₂) averaged about 25 atoms thick. By continually reducing the gate oxide thickness and the length of the gate electrode, the semiconductor industry has doubled the transistor's switching speed every 18 to 24 months according to the Moore's Law.

This has worked remarkably well, but problems exist. One is that the oxide often permits boron penetration from the gate into the threshold region, degrading the threshold voltage and device performance. The other problem is that as device size shrinks, the gate oxide becomes so thin that “tunneling” currents arise from the gate through the oxide to the substrate, again degrading the device performance.

To overcome the first problem, transistor engineers have developed solutions involving stacked gates and various nitridation techniques. Nitradation adds nitrogen to the silicon dioxide. A successful two-step oxidation/nitridation approach using a sequential in situ steam generation and rapid plasma nitridation process shows a 5-7× reduction in leakage current compared to SiO₂ at an effective oxide thickness of less than 20 A (or Angstroms).

The second problem relates to current tunneling through very thin oxides. This problem is more difficult and thought to require a change of materials. The tunneling current rises very quickly as the oxide is thinned down. It is believed that below about 14-15 A, new material must be used to replace the silicon dioxide. One would look for a thinner but defect-free SiO2 film to avoid the excessive leakage current. The new high-k materials must be used in place of the 14-15A SiO2 layers. Some solutions are possible, but none fit all needs.

The new insulating material must also have the right dielectric constant and be compatible chemically with silicon to get the right interface. Interface micro or atomic engineering may in fact be the key factor that will allow the new or old materials to continue the scaling of field-effect transistors (FET).

The defect-free gate dielectric layer must be put down uniformly in a thin film to tolerate subsequent silicon processing and temperature cycling. There is still no suitable high dielectric constant material and interface layer with the stability and interface characteristics to serve as a gate dielectric.

Metal silicates may be good candidates. Halfnium and zirconium silicates are stable in contact with silicon, between substrate and dielectric. Tantalum pentoxide is also available.

Even with a material other than SiO₂, a very thin SiO₂ layer will probably still be required at the channel and/or gate electrode interface to preserve interface state characteristics and channel mobility. A major problem with a material other than SiO₂ is the probability that a very thin SiO₂ layer will still be required at the channel and/or gate electrode interface to preserve interface state characteristics and channel mobility. This would severely reduce any benefits due to the high-k dielectric.

It has been suggested that the first 10 A above the silicon substrate largely determine the leakage properties of the dielectric and the carrier mobilities in the channel underneath. Once past that, only the bulk properties of the film needs to be dealt with. Controlling these properties will be critical to the success of high-k materials. Some hope exists to shrink the silicon dioxide down to 0.1 um (or microns) thick using plasma nitridation t control the first 10 A or so of the dielectric.

The gate material is often a doped poly-silicon with a silicide on top. Interest exists in switching the polysilicon to a metal due to depletion effects associated with the poly. When the device is turned on, the poly-silicon actually depletes a little bit making it look like a thicker oxide. This depletion effect leads to less drive current—a characteristic of a semiconductor material rather than a metal.

The now used high dielectric (k) material is moving from the doped polysilicon to a metal. The advantage of metal gates is that this depletion effect is avoided, and the gate resistance is lowered. However, there are two disadvantages to metal gates. The metal work function of the gate is fixed by the choice of metal. By comparison, the work function in poly-silicon is controllable by varying doping of either n-type or p-type. This allows optimization of the threshold voltages for both the re-channel and p-channel transistor, not possible with metal.

The main focus of present transistor engineering effort is to maximize the drive current. The present transistor is a current source charging a large capacitor. The higher the current source and the smaller the capacitance, the faster it charges. All the industry's scaling efforts are towards improving the drive current at lower voltages. Second to optimizing drive current is a need to reduce parasitic capacitances at the device levels and the interconnect level. Hence, high-k material for the gate electrode dielectric is moving from doped poly-silicon now used to a metal.

Sixteen (16) ion implantation steps are commonly used to create the sources and drains for the PMOS and NMOS devices, and the retrograde wells in which they sit. Implantation is also used to dope the gate and to provide the “punch-through stop” pockets. After the implantation, the device must be annealed at a relatively high temperature to remove the implantation damages, to “activate” the dopants, and to insure that all dopant atoms lie exactly where needed.

The junction depth for source/drains should be only 35-70 nm deep for the 100 nm (or 0.1 um) generation due to go into production in 2005. Drain extensions should only be 20-33 nm deep. The abruptness of the source and drain extensions is critical. There are still no known solutions in several areas.

Many believe computer modeling will help researchers determine the optimal doping profile and study the impact of various process parameters on dopant diffusion. A few degrees in temperature can have a significant effect on the doping profiles. Aggressive scaling of the transistor source/drain junction depth requires production worthy (milliamps for 300 nm wafers) ion beam current at sub-Key energies for boron. The requirement for sub-Key implants is primarily driven by the need to reduce transient enhanced diffusion. Sputtering related dopant loss and other phenomena will most likely preclude the use of sub-Key implant energies below 0.5 Key, regardless of available beam current.

Reducing the implant energy, annealing time and dose are of primary importance for achieving the shallowest junctions. Ultra-fast ramp-up rates are of secondary importance—their potential benefit can only be captured with an equally fast ramp-down rate not achievable in today's rapid thermal processing systems. Several combinations of implant and annealing parameters (implant energy, dose and annealing temperature, time and ramp rates) are possible that yield the same junction solutions. It is essential to select solutions which optimize manufacturability.

The semiconductor industry continues to double device functionality every two years or so. It is thought this requires switching to new materials. Instead of aluminum, silicon dioxide and poly-silicon structures, some think that future integrated circuits will be built from copper, low-dielectrics and high-k dielectrics, and “exotic” metals like hafnium and zirconium.

The traditional silicon dioxide insulator needs close thickness control and low defect density. These may be met by improved cleaning and oxidation techniques. As the required layer becomes thinner, leakage currents and reliability problems arise. Direct tunneling can occur in very thin layers, giving high leakage current. At 100° C., the maximum voltage rate of a 2.5 nm thick layer of silicon dioxide is only 1.5 v.

A silicon/dual-doped polysilicon gate stack process is used as the mainstay of CMOS device manufacturing since its inception. To replace this process, the new CMOS gate stack process, considered to be the most important film layer in integrated circuits, would require high-k dielectric gate insulator, with a dual metal gate electrode. The use of this new process should be no later than five years. This is generally thought impossible.

A flowable oxide based on hydrogen silsesquioxane is often used to form ultrathin low-k insulating layers. Use of these layers reduces parasitic capacitance and thus shortens propagation delays. These changes increase by 30% the within-chip processing speed, as compared with other 180 nm CMOS processes.

The use of tungsten instead of aluminum allows fabrication of conductor widths down to 240 nm below the normal metal layers at gate level. The extra routing flexibility achieved by the local interconnect layer enables the silicon area to be reduced by some 10% to 20% in typical core cells. It also permits the spacing between tracks in the first metal layer to be considerably increased, reducing defects in this layer and increasing the yield despite the extra process step.

The traditional silicon dioxide gate insulator presented challenges, such as the need for close thickness control and low defect density. These are thought with improved cleaning technology and oxidation techniques. As the required layer becomes thinner, leakage currents and reliability presented problems. Direct tunneling can occur in very thin layers, resulting in high leakage current. At 100° C. the maximum voltage rating of a 2.5 nm thick layer of silicon dioxide is 1.5 V.

High-k dielectrics is one of the major road blocks in device scaling. With extremely smooth gate dielectric and very small channel length, the transistor drive current goes ballistic, increasing the input current flows via the channel from the usual 35% to 85%. The remaining input current collides with the rough edges of the insulating layer.

Low-k polymer dielectrics have been used to replace glass insulators to separate the new copper wires in the new chips. Copper lead wires are also replacing aluminum wires. This material combination will push chip speeds to about one-third faster than today's fastest chips. There are, however, problems to using this system: 1) the plastic is much softer than glass and does not stay in place, making it difficult to make the chips; and 2) these polymers also do not stick to other materials including silicon and other polymers.

Tungsten is replacing aluminum interconnects. The use of tungsten reduces the conductor widths down to 240 nm below the metal layers at gate level. The extra routing flexibility achieved by the local interconnect reduces 10-20% of the silicon area. The spacing between tracks in the first metal layer can be considerably increased to reduce sensitivity of this layer to defects thereby increasing the device yield. However, the very high tungsten density of 19.3 (vs 2.7 for Al, 2.33 for silicon and silicon dioxide) induces deboning from other materials during fast accelerations and decelerations, as shown later.

The capacitance between the gate and channel of an insulated gate FET needs to be high, but in small area devices this cannot be achieved by using a very thin silicon dioxide layer, or the leakage current will be too high, most likely due to material imperfections. A polysilicon gate electrode has been used with germanium doping to control the work function of the material. A variety of metals will be tried as gate electrodes, with TiN/Al or TiN/W being the most likely candidates. Also considered are deposition of high-k gate insulators by the atomic layer chemical vapor deposition technique using aluminum oxide, hafnium oxide, titanium oxide, zirconium oxide and silicates of zirconium and hafnium.

Ballistic effects occur around the 30 nm channel length when the electrons emitted from the source arrive at the drain without scattering. Small dimensions have great impact on the electrons. The channel lengths of conventional transistors are so long that electrons seldom go all the way from the source to the drain without scattering. But when the channel length gets down to around 35 nm, the ballistic component increases and device performance improves. However, once ballasting occurs, further reduction of the channel length no longer improves the performance. Electrons travel better when the gate oxide is slightly thicker because they are less attracted to the gate directly above the gate oxide layer.

There still is plenty life left in traditional gate structure. Take, for example, the “ballistic nanotransistor”. In these devices, dramatic gains in drive current are possible simply by combining a very smooth gate dielectric with a short channel length, such as in Vertical MOSFET. The main challenge is to replace the traditional silicon dioxide/dual-doped poly-silicon gate stack process. This process has been the mainstay of CMOS device manufacturing since its inception. The new CMOS gate stack process will require the cost-effective, low-temperature integration of nanometer scale high-k dielectric gate insulators, with dual metal gate electrodes. The replacement should be within five years. History has shown, however, that changes of this magnitude normally require ten years or more to implement.

The very slow process in finding new semiconductor materials is looming as a grand challenge in chip design. There are still many, many problems that are material-limited particularly for new improved devices. New material selection, design, and processing methods must be found and made. The whole manufacturing process is generally too complicated involving, e.g., too many materials and equipment to achieve high repeatability and good device yield, performance, and repeatability. Most of the materials are not applied in optimal ways. This invention will address many of these issues.

### BRIEF SUMMARY OF THE INVENTION

A method of mass-producing an atomic or molecular semiconductor device comprises supplying a solid state material substrate, providing two adjacent semiconductor pockets and forming a gate layer less than 10 Angstroms thick, having atomically smooth major surfaces; and perfectly chemically bonding, uniformly and defect-freely, this gate layer onto the substrate to improve and manage the device yield and performance.

To overcome the foregoing and other difficulties, the general object of this invention is to provide an improved, semiconductor or solid-state integrated IC with improved performance, yield, cost, and miniaturization;

Another object of the invention is to provide vastly smaller but improved, atomic solid state devices, each with an interfacial electrically rectifying barrier region of the PN junction, metal-oxide, or metal-semiconductor type;

A broad object of the invention to provide an integrated semiconductor circuit with thin-film isolating material layers to form at least one of the critical parts thereof;

Another object of the invention is to provide a new, improved gate layer that can be easily and rapidly produced to near perfection at high yield and low cost;

Yet another object of the invention is to provide a new, improved field isolation layer that not only improves circuit performance but allows further miniaturization;

A further object of the invention to provide an integrated semiconductor circuit with an isolating material layer which is sufficiently thin and flexible, thereby not only advancing device miniaturization, but improving the performance of the circuit and minimizing thermal or volume expansion mismatch stresses on the circuit;

Another object of the invention is to provide a new generation of low-cost environment-resistant flexible circuits;

Another object of the invention is to mass-produce single-atom or single-molecule IC selectively operative in a single-electron, single-hole, single-carrier, or single-photon mode;

A still further object of the invention is to mass-produce, on a single chip and with minimum number of processing steps and at low cost but high yield, thousands or millions of transistors more miniaturized than is presently possible; and

A still another object of the invention is to provide highly miniaturized electro-optical three-dimensional, two-dimensional, or one-dimensional atomic or molecular diode or transistor arrays especially suitable for optical telecommunication.

### BRIEF DESCRIPTION OF THE DRAWINGS

Various other objects, features, and advantages, and a more complete understanding of the invention, will become apparent to those skilled in the art from the following description and claims, taken in conjunction with the accompanying drawings.

For the purpose of illustrating the invention, there is shown in the drawings the forms which are particularly preferred. It is understood, however, that the invention is not necessarily limited to the precise arrangements and instrumentalities here shown but, instead, may combine the same described embodiments or their equivalents in various forms.

FIG. 1 is a partial vertical cross-section of a prior-art Fairchild's Isoplanar MOS device with a flat-bottomed and mostly straight-sided isolating groove;

FIG. 2 shows partial vertical cross-section of Li's prior-art isoplanar device with a round-bottomed and sloping-sided isolating groove of zero width;

FIGS. 3(a) and 3(b) show partial vertical cross-sections of a prior-art intrinsic conductor-insulator-semiconductor (CIS) device in Li's Ser. No. 154,300 application;

FIG. 4 is a vertical cross-section of a MOS or CIS device showing a new extremely thin, curved gate layer;

FIG. 5 shows a MOS or CIS device showing a narrow, thin-film curved or wavy field insulating layers or walls separating the device components; and

FIG. 6 is an atomic or molecular IC showing a mixed semiconductor-insulator solid-state device.

### DETAILED DESCRIPTION OF THE INVENTION

Various other objects and advantages, and a more complete understanding of the invention, will become apparent to those skilled in the art from the following description and claims, taken in conjunction with the accompanying drawings.

Several of the prior-art methods, described below, are useful or even necessary to make the small high-precision semiconductor circuits of the present invention:

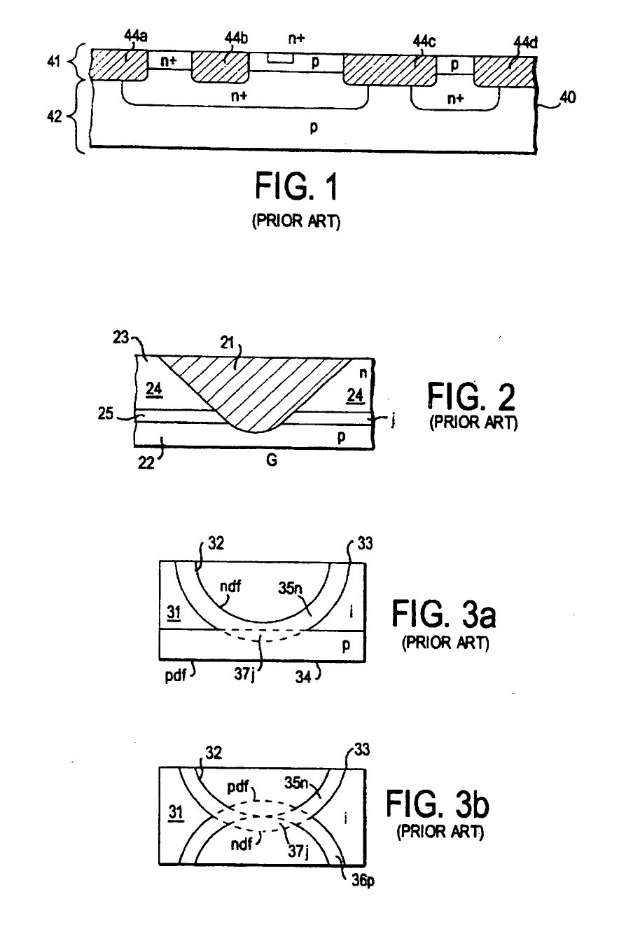

1) As shown in Li's Pat. Nos. 3,430,109 and 3,585,714 patents, one can use a number of microscopically precise methods to remove materials on, or implant foreign atoms into, the device wafer:
a) mechanical grinding or polishing with realtime feedback control (See: U.S. Pat. No. 3,430,109, FIG. 1 and col. 2, lines 38-64 (or U.S. Pat. No. 3,430,109:2/38-64);
b) precision chemical etching using repeated masked chemical etchings immediately after pre-cooling to prevent localized, nonuniform or preferential deep etching at dislocations and subgrain boundaries (U.S. Pat. No. 3,585,714:11/75-12/59);
c) energetic particles bombarding with aligned or focused ion, electron, proton, or laser photons (Pat. No. 3,585,714:11/24-42). Such energetic particle beams of Argon atoms, electrons, photons can locally heat up or energize the intercepting surface atoms to evaporation or ejection. Ions and proton beams of selected foreign atoms, such as O, N, Si, Ge, Ga, B, P, As, can also be very precisely implanted into semiconductor wafers;
d) combination of the above methods; and
e) the precision grooves so made are of many types: cylindrical, ellipsoidal, spherical, or conical as described by Sanders et al. but invented by Li in the '109 patent, with a radius of curvature of 1 cm, 0.1 cm, 0.001 cm, 0.1 micron, down even to one or a few atoms or molecules in sizes in this invention.

Laser processing and ion implantation are particularly important. Laser beams can be controlled by simple stable optics, while electron and ion beams by electrostatic deflecting means. According to Li in his prior cited references, all the above methods may automatically provide sensors to realtime monitor the degree or progress of the removing material from, or introducing material into, the device wafer. This realtime self-optimizing, closed-loop feedback control (See Li's U.S. Pat. Nos. 6,513,024 and 6,144,954).

Using these prior-art methods, this invention methods of making solid state integrated circuit devices and more particularly to methods of making improved, miniaturized semiconductor integrated circuit devices to achieve very high resolutions and nano or even atomic accuracy otherwise impossible. For example, precise depressions or grooves in silicon can be accurate to nanometers or angstroms in dimensions in sizes, lengths, widths, depths, or thicknesses, accuracies, precessions, curvatures, shape, chemical composition profiling, and lateral locations from other components.

In the real-time self-optimized process control of IC manufacturing, the thickness of the semiconductor or insulating material layers or even the PN junction regions being formed or processed may be the sensing medium, without any extraneous outside equipment or component material. The sensed data may include optical transparency, electrical resistances, thermal conductivities, leakage currents, and other electro optical properties of the semiconductor or insulating layer materials.

The gate and field isolating layers of MOS transistors are usually made by thermal oxidation or nitridation. Thermal oxidation of silicon with Si₃N₄ masks was well known prior to 1968. See, e.g., V. Y. Doo in “Silicon Nitride, A New Diffusion Mask,” IEEE Transactions on Electron Devices, Vol. 13, No. 7, 1966, pp 561-563. For masking in thermal nitridaiton, various metal layers such as Ni, Au, Pt may be used.

As an alternative to thermal oxidation or nitridation, oxygen and nitrogen may be introduced into the silicon by ion or proton implantation. Under an implanting voltage of one megavolt, for example, oxygen and nitrogen ions can be introduced into silicon host to a depth of 1.7+/−0.13 um and 1.87+/−0.12 um, respectively. Because of its excellent spatial and dose control and ease of manufacture, ion implantation has become the most prevalent method of adding foreign atoms into semiconductors.

Shockley, Gale, Kellett et al, Sibley, and Wilson invented various important ion implantation techniques, disclosed respectively in U.S. Pat. Nos. 2,787,564; 2,434,894; 3,341,754; 3,326,176; and 3,563,809. These scientists showed the unique features of implanted ions including:

1) straight penetration without appreciable lateral diffusion to give orders of magnitude sharper boundaries than the usual thermal diffusion;

2) controlled size of the implantation region down to less than 1 micron, with an accuracy of 1,000 Angstroms (0.10 microns) down to 10 Angstroms;

3) the ions can be implanted without masking, wet chemistry, and photolithography;

4) the implanted region need not start at the surface of contact with foreign matter;

5) the shape and three-dimensional chemical composition of the ions can be controlled to fractional micron accuracy;

6) when used for PN junction or oxide/nitride groove formation, the chemical composition profiles and, in particular, critical PN junction grading, can be of any selected shape, rather than only the exponential or erfc grading obtained with thermal diffusion, respectively for limited or infinite surface diffusion source by thermal diffusion;

7) computer programmed control to deflect implanted ions to “write” with a collimated ion beam of selected mass to produce a predetermined integrated circuit pattern on the workpiece ('176:2/20-62); and

8) methods of introducing precise amount of impurities, such as oxygen, are available to achieve, even in a single implanting step, exact three-dimensional control in shape, size, location, and chemical composition to fractional micron or even atomic accuracy by modulating the energy, current, duration, and position of the ion beam, and the use of Li's computerized self-optimizing process control, apertured masks, moving wafers, and ion deflection or separation systems.

Silbey in his patent No. 3,326,176 already disclosed “writing” with ion beams of selected mass. Recent developments allow the exact positioning of single atoms on a substrate. In 1999, Cornell University researchers observed atomic bonds by combining scanning tunneling microscope with vibrational spectroscopy. This technique makes it possible to individually move atoms or molecules to create very atomic or molecular structures. The scanning tunneling microscope not only won for the researcher a Nobel prize but has become the standard worldwide “tweezers” to sculpt nanotechnologically, atom by atom or molecule by molecule. Letters of single atoms have, for example, been written on silicon substrates. Conferences on manipulating single atoms into precise positions and other related topics such as atomic-layer CVD and molecular atomic spectroscopy are common these days.

I hereby incorporate these ion implanting and atomic writing references into this application.

A very brief review of materials commonly used in electronic material is in order. The semiconductor transistor structures that we know today have been built on four basic materials: silicon at the base, silicon dioxide as an insulator, silicon nitride for the side wall, and aluminum for interconnect.

These and other substituting electronic materials vary greatly in electrical resistivities. For example, the resistivities of metals such as Al, Cu, Au, and W are in the range of 1 to 10 Microcom-cm, and those of insulators such as diamond, glass, and quartz are 10 to the 10-18 ohm-cm. Semiconductors, such as Si and Ge, have resistivities that lie in between metals and insulators.

After doping by thermal diffusion or ion implantation, a semiconductor can have very low resistivities close to metals, to remain as a semiconductor, or to have very high resistivities close to insulators. In the last case, e.g., intrinsic semiconductor silicon or germanium, the valence and conduction bands of the perfect silicon is totally filled. There are therefore no electrons or holes that can be accelerated, and no current can flow. A perfect or intrinsic crystal of silicon acts, therefore, as an insulator useful for metal-oxide-semiconductor (MOS) or, broadly, conductor-insulator-semiconductor (CIS) devices.

That such a practically useful MOS or CIS device is possible can be seen as follows. Conventional MOS devices sold by the millions or billions have gate oxide layers which actually are not pure silicon dioxide layers at all. This is because the oxide is in-situ thermally oxidized from, or ion-implanted into, not a pure silicon substrate, but an impure silicon substrate containing parts-per million (ppm) or more of impurities such as Al, Na, Fe, Mg, Ca, P, B, As, Sb, O, N, and the like. The so-called “silicon” used to produce the oxide is actually a complex silicon alloy of many chemical elements. The “silicon dioxide” formed on this impure silicon alloy is also actually an impure silicon dioxide compound containing various insulating, semiconducting, or even conducting oxides of different metals or metal alloys in various proportions. Nevertheless, such an impure silicon dioxide material form extremely useful gate or field oxide layer materials on all the billions of existing “silicon” integrated circuit devices.

As shown above, an ideally intrinsic silicon material is an insulator. Depending on its purity, a practical intrinsic silicon material can be sufficiently electrically insulating, in comparison to or when used in combination with the p-type “silicon” substrate and n-type “silicon” pockets, to form the gate or field oxide layers of a practically useful MOS or CIS device. As will be shown shortly, such an intrinsic silicon MOS or CIS device is, at least as to environmental resistance, distinctly better than the convention MOS or CIS devices, even though they may be less pure and, therefore electrically more leaky.

The use of an intrinsic silicon isolating field insulating groove to replace the common field oxide isolating groove was disclosed as early as Sep. 23, 1968 as FIG. 3 in Li's application Ser. No. 154,300. Such a groove was first claimed in Li's application Ser. Nos. 08/483,937 and 08/483,938, both filed on Jun. 7, 1995. I hereby incorporate by references these three prior Li applications into this application.

In this and all these and intervening applications, the intrinsic device of FIG. 3 is shown to have an isolating intrinsic silicon groove 32. This groove is formed into a cylindrically grooved top surface 33 of a slab or wafer of intrinsic semiconductor material 31 (FIG. 3a). Next, n-type and p-type dopants are diffused into the intrinsic silicon 31, respectively downward from the cylindrically grooved top surface 32 and upward p-type diffusion from the flat bottom surface 34 (in FIG. 3a) to produce the n-type diffusion region 35, and the p-type diffusion region 36. A PN junction region 37 is then formed which is surrounded on all its periphery by isolating intrinsic silicon 31. The same junction region can be planar or curved, depending on the surface concentration of the n-type and p-type dopants and also on the slab thickness. See, e.g., application Ser. Nos. 08/483,937 and 08/483,938.

In the device of FIG. 3a, the downward diffusion of the n-type dopant from the grooved, top cylindrical surface forms in the inert or intrinsic silicon material 31a generally cylindrical n-type diffusional front (ndf) 35. This diffusional front is generally concentric with the cylindrical grooved surface 32, according to the laws of diffusion. The upward diffusion of the p-type dopant from the planar bottom major surface 34 of the intrinsic wafer 31 forms a generally horizontal and planar p-type diffusional front (pdf) 36. The PN junction region 37 must form where n-type and p-type dopant concentrations in the wafer are substantially equal, below the generally planar p-type diffusional front but above the generally cylindrical n-type diffusional front.

The PN junction region 37 is generally curved by virtue of the cylindrical n-type diffusional front being pushed up and also flattened by interaction with the planar p-type diffusional front. In this way, the PN junction region has a central horizontal portion that continuously extends sidewise and monotonically curves up from the central horizontal portion, to terminate at a right edge portion having a substantially positive slope in a first quadrant and at a left edge portion having a comparably substantial but negative slope in a second quadrant. Looking from the top, the PN junction is concavely curved.

The p-type diffused material 36 forms the substrate of the intrinsic semiconductor device. This diffused material has the same substantially planar similar to the bottom major surface 34 of the FIG. 3a device. In a first cross-sectional plane oriented normally of the bottom major surface, a left part and a right part of the PN junction region 37 are curved and nonplanar, and substantially symmetrical to each other with respect to another cross-sectional plane oriented normally of both the bottom major surface and the first cross-sectional plane.

The left part and a right part of the PN junction region 37 are also substantially symmetrical to each other with respect to the another vertical cross-sectional plane. Also, in the first vertical cross-sectional plane, a left part and a right part of each of the p-type diffused material 36, n-type diffused material 35, and undiffused still intrinsic material 31 have prespecified varying thicknesses, and are substantially symmetrical to each other with respect to the second vertical cross-section plane normally of both the major bottom surface 34 and the first vertical cross-sectional plane.

In addition, both the top and bottom major surface of the n-type diffused material 35, and the top major surface of the p-type diffused material 36, and the top and bottom major surface of the PN junction region 37, are all curved in substantially the respective entire portions thereof.

Compared to the FIG. 3a device, the device of FIG. 3b has somewhat different features as to the n-type 35 and p-type 36 materials, the remaining intrinsic semiconductor 31, and the PN junction region 37. The PN junction region 37 is also be curved unless the radii of curvatures of the top and bottom pre-diffusion cylindrical grooves and the p-type and n-type diffusion conditions are identically the same.

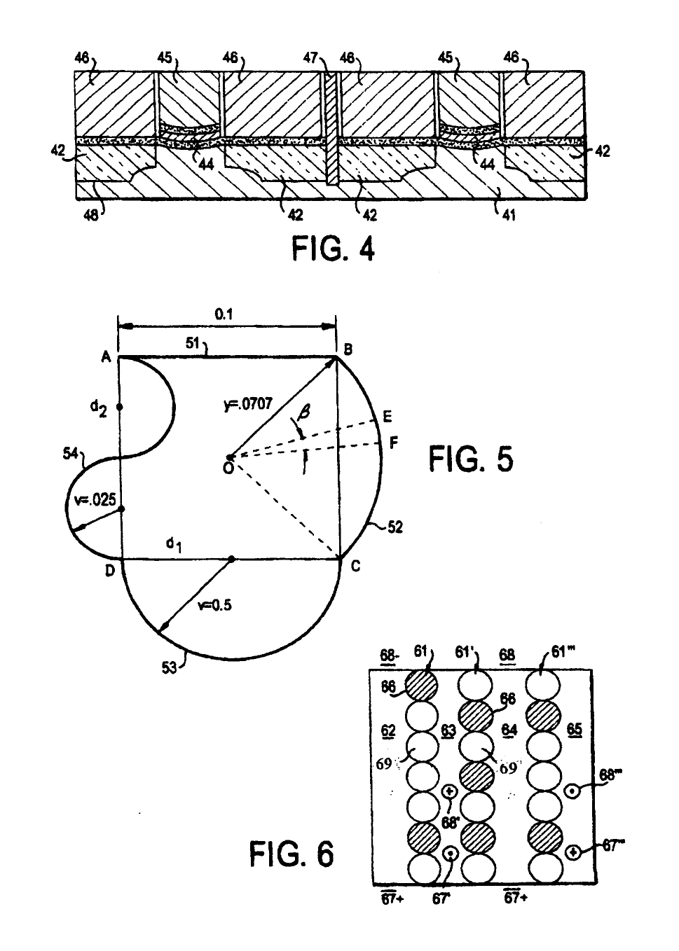

In a preferred embodiment for making the new gate layer of this invention, a laser system is used. The integrated device of FIG. 4 has a p-type silicon substrate 41, on which there are adjacent but laterally spaced-apart n-type silicon pockets 42. PN junction regions are formed where the n-type semiconductor pockets 42 contact the p-type substrate 41. The adjacent silicon pockets 42, respectively a source region and a drain region, are laterally spaced apart by a gap of a prespecified gate length (e.g., 0.001-0.1 microns) on a top surface of the substrate in the gate area. For extreme dynamic resistance, both the substrate 41 and pockets 42 may be nearly intrinsic silicon material, respectively slightly p-type and n-type doped. The gate area has a length roughly the same as, but slightly greater than, the prespecified gate length to minimize leakage.

In one preferred embodiment, the gate layer is an oxide/nitride or even an intrinsic silicon material. This intrinsic material can be an equally n-type and p-type doped silicon leaving few uncompensated dopants producing an electrically inert silicon material for the device.

The gate layer 44 may be formed with such a material in such a structure as to be sufficiently yieldable or flexible to minimize effects thereon of thermal mismatch stresses between varying materials of the contacting substrate, pockets, and gate lead. This design significantly improves the performance and reliability of the semiconductor circuit device. With this improved gate layer, the useful life of the old silicon dioxide/nitride materials may be extended further into smaller devices.

A pulsed laser system is preferably used to form this gate insulating layer of an intrinsic silicon device. One may use, for example, a 1.5-KW carbon dioxide laser from Convergent Energy, a Q-switched 10-W system from Spectra Physics, or a 3.9 kW to 400-W-average pulsed Nd:YAG laser from Lumonics. The gate layer of the substantially electrically insulating, intrinsic silicon material is centered on the gate area but laterally extending slightly past edges of the pockets to prevent leakage.

The critical gate layer of the transistor should, of course, be as perfect and tenaciously attached to the substrate as is possible and practical. But for the conventional straight or planar gate layer design, neither perfection nor tenacity is possible. When a very thin, flat, and imperfect gate layer 44 of material A (e.g., silicon dioxide) is attached to a flat substrate of material B (e.g., silicon), the thin, imperfect gate material A always fails when the transistor is thermally cycled due to repeated switched on-and-off. This is so regardless of any practical combinations of materials A and B, and generally regardless of how the two materials are formed. Material B is simply too thick compared to the much thinner, more fragile and defective material A. The same inevitable thermal mismatch stress simultaneously applied onto both materials always fails material A, and not B. The thin material A will fracture into many small pieces whose sizes depend on the thickness of material A.

A thicker flat layer of the same material A, if inadequately chemically or metallurgically bonded and not simply physically attached to material B, still fails by peeling or flaking off as larger pieces. These universal failure modes have been repeatedly observed in the semiconductor and other industries.

Four solutions to this thermal and thickness mismatch problem are possible:

1) selecting materials A and B to be as close in chemical composition as possible minimizing differences in thermal coefficients of expansion in the first place;

2) making the entire IC including the gate layer laid on the semiconductor layer so thin that the circuit is flexible to minimize mismatch strains and stresses;

3) forming a curved gate layer material which minimizes thermal mismatch stresses through curvature-related stress-relieving effects explained elsewhere and also to be explained shortly; and

4) perfectly chemically or metallurgically bonding materials A and B.

This invention uses all these four methods. Solution (1) is self-evident. Solution (3) will be more fully explained shortly in the formation of the new field insulation layer. For solution (4), please refer to U.S. Pat. No. 5,874,175. This patent discloses techniques to perfectly and strongly bond two materials with widely different coefficients of thermal expansion, even over large areas and with very thin bonding layers.

To understand solution (2), one should briefly review interaction forces between two neighboring atoms. According to the commonly used Leonard-Jones model, the forces between two neighboring atoms have two superimposed force components: a far-field attractive force which increases with the sixth power of the distance between atoms, and a near-field repulsive force which increases with the twelfth power of the distance between two atoms. When the two atoms are far apart, repulsion is negligible. When nearby, repulsion is predominant. When the two atoms are in equilibrium, the attractive and repulsive forces must be equal to a common equilibrium force.

According to this atomic model, an atomic chain or sheet a few angstroms in diameter or thickness for silicon can easily bend or flex enough to accommodate any thermal mismatch strain. The bending occurs when one or both atoms simply rotate around its neighbor without changing the distance there between. There is therefore no work done or energy consumed, since both the repulsive and attractive forces depend only the interatomic distance, which is constant before and after the bending. Nor are there any gain or loss of energy, due to either the attractive force or the repulsive force component. This has been observed even in “brittle” materials such as oxide ceramics, e.g., SiO₂.

Note that the attractive and repulsive forces decrease continuously, not abruptly. There should be no abrupt breaks or failures in the atomic chain or sheet, as we usually see on the conventional stress-strain testing curves. The abruptness results from force interactions among billions or more atoms, not two or several atoms.

To bend a wire or sheet of only 0.1 mm thick, for example, an atom at the center of the wire or sheet may, if completely free, monoatomic in thickness or width, and not embedded in the semiconductor silicon layers a 62 and 63, easily bends or flexes enough to accommodate any thermal mismatch strain. The bending or flexing is accomplished by rotating around its nearest neighbor with little strain, stress, or work done. But the atom at the periphery is space some 100,000 atoms away from the central atom or atoms. The strains at the peripheral atoms, multiplied by the Young's modulus, are much greater than any tensile, shear, or even compressive strength of the material. Also, about 10¹¹ atoms must be simultaneously involved requiring extensive plastic deformation work and energy loss.

An embodiment of the FIG. 6 device comprises a chain or sheet of mixed doped silicon atoms 65 (hatched) and insulating materials such as intrinsic silicon atoms 66 or oxide/nitride molecules 66 (in white). Dopants for the hatched semiconducting silicon atoms include n-type dopant P and Sb, and p-type Al and B. These chains or sheets of semiconducting and insulating atoms (or molecules) 62, 63, 64, and 65 are embedded in p-type semiconducting layers 62 and 64, and n-type semiconducting layers 63 and 65.

What happens if one or more atoms in the chain or sheet, such as those special cross-hatched impurity atoms 66, are of a material different from those of the other semiconducting silicon or germanium atoms layers 62-65, or other molecules such as GaAs, InP, GeSi, or GaAlP, of the chain or sheet such as GaAs, InP, SiGe, or GaAlP? This depends, of course, on the properties of the special atom or molecule in the chain or sheet relative to those in the layers 62-65, especially their comparative electrically resistivity types and values.

Consider the simplest atomic silicon chain 61, if the special impurity atom or molecule 66 differs in resistivity values from the other atoms 69 in the chain or sheet by one or two orders of magnitude, or is metal-like or semiconductor-like, a new thin-film solid-state device or circuit then results, with film layer thicknesses ranging from several submicrons down to several or even one atomic thickness, then results. Such device may be a single-electron, single-hole, single-carrier, or single-photon device, for reasons shown below.

In a preferred embodiment of the FIG. 6 device, the entire atomic chain or sheet 61, 61′ or 61″ is only one-half micron through several atomic layers to even one single atomic layer wide or thick. This chain is mostly of unhatched intrinsic silicon or oxide/nitride molecules 69, but still has some hatched atoms of, e.g., P, Sb, Al, or B-doped silicon (66). The unhatched part, if perfect, forms a good insulating wall.

The semiconductor region 62 to the left of the chain or sheet 61 in the FIG. 6 device is here of the p-type semiconductor, while the semiconductor region 63 to the right of the chain or sheet 61 is of a n-type semiconductor. A doped silicon atom 66 of either type on the same chain or sheet will then form an atomic diode.

For example, as shown in FIG. 6, any n-type doped semiconductor atom 66 with five electrons on each atom present on the chain 61 will join the n-type semiconductor material region 63 to become part thereof. The intrinsic silicon atoms or oxide molecules 69 for the isolating wall 61 electrically isolates the left p-side 62 from the right n-side 63, except where the impurity-doped semiconductors atoms or molecules 66 is located forming thereat an atomic or molecular PN junction and a selected leakage or drift path.

The p-type region 62 has an external positive electrode 67 at the bottom of the semiconductor region 62 and an external negative electrode 68 at the top. The n-type region 63 has a negative electrode 67′ at the front, and a positive electrode 68′ at the rear. An external electrical field is thus produced in the region 63 causing the holes to drift toward the front of the region 63, and the electrons toward the rear in the same region.

When a light beam, such as from a laser beam, shines on the p-type material region 62 in FIG. 6, an electron-hole pair of carriers is locally generated in the region due to photon injection from, e.g., a laser diode beam. A laser diode can produce a ray of light at a precise wavelength and can modulate the amplitude of the light at very high frequencies without distortion by using a special optical fiber capable of lazing at the same wavelength. An optical array of laser diodes emits multiple laser beams useful in, e.g., an optical communication system. The device of FIG. 6 then can form, e.g., an optical reader.

Of the photon-generated hole and electron, the electron will be instantly recombined with a hole right where it is generated in the p-type semiconductor region 62. The hole lost by this recombination is replenished by the bottom positive electrode 67, supplying the hole needed to maintain charge neutrality in the region 62 and creating a first electrical signal.

The freed hole from the electron-hole pair in FIG. 6 will then: a) drift vertically upward through the field 67-68 to the nearest n-type impurity atom 66 and the associated PN junction field; b) be pushed rightward by the PN junction field into the n-type semiconductor region 63; c) instantly recombines with an electron in the electron-dominant n-type semiconductor region 63; and d) causes the back negative electrode 67′ to supply an electron needed by the region 63 to maintain its charge neutrality, creating a second electrical signal.

The movement of the freed hole through the atomic PN junction at the impurity atom 66 and the supply for the lost electron by electrode 67′ are done one at a time. Hence, the name single-carrier (hole or electron) semiconductor device. The hole-electron pair are generated by the impact of a single photon. Hence, the device of FIG. 6 is also a single-photon or single-particle device.

The externally applied electrical fields from the external electrode pairs 67-68 and 67′-68′, and the mobilities of holes and electrons in semiconductor silicon are known. The distances of carrier travels are related to the designed device structure of the insulating atoms 69 and the specified distribution of the doped semiconductor atoms 66 on the chain or sheet 61. Hence, the first electrical signal representing replenishing the lost hole in the p-type semiconductor region 62 and the second electrical signal representing replenishing the lost electron in the n-type region 63 have predictable time delays after the laser photon impacts on the device to generate the electron-hole pair.

These delay times can also be computer simulated or actually sample or model tested. The device of FIG. 6 thus is a useful optoelectrical device for monitoring, e.g., laser photon injections as to their exact locations, times, vertical and horizontal or front and back distances on the insulating chain or sheet 61, and horizontal front-to-back distances in the semiconductor region 63, frequency of photon injections and carrier pair generations.

Decreasing the thickness of the p-type layer 62 and lower the light aiming point on region 62 in the device of FIG. 6 increases the sensitivity and reduces the delay time of the first electrical signal after the laser injection. Maximum sensitivity and minimum delay time of the first electrical signal in region 62 are obtained with minimum thickness of the p-type semiconductor layer 62, which is shown as continuous white vertical area in FIG. 6 but actually is filled with one to several or more columns of the insulating atoms or molecules 69.

Maximum sensitivity and minimum delay time for the second electrical signal in the n-type region 63 is achieved with a minimum distance the photon-generated carriers must travel before getting through the gate at the impurity atom 66. Regulating the thickness of the region 62 thus also changes the sensitivity of the optical reading or light-sensing device. Monitoring the first electrical signal alone provides a one-dimensional sensing device for the vertical direction.

Maximum sensitivity and minimum delay time for the second electrical signal requires the minimum thickness of the n-type layer 63 but a laser aiming point in region 62 closest to the negative electrode on the back of the region 63. The thickness of layer 62 can also be changed to regulate the sensitivity of the second electrical signal on the device if the photons strike only on the p-type layer 62. Monitoring the second electrical signal alone provides a one-dimensional light-sensing device for the horizontal direction from the front to the back surfaces of region 63. Hence, monitoring both the first and second electrical signals provides a two-dimensional light-sensing device for both the vertical (or top to bottom) and horizontal (front to back) directions.

Photons striking from the left of the device generate hole-electron pairs which travel the least distances in region 62 when collected by electrodes 67-68. The same carriers have to suffer transmission losses through silicon and oxide or doped atoms 66 before their collections. One transmission loss is suffered for collections by electrodes 67-68, two for collections by electrodes 67′-68′, three time for collections by electrodes 67″-68″, and so on.

The insulating chain or panel, . . . may not be atomic but have appreciable width in a direction normally of the paper in FIG. 6, and also in depths extending horizontally toward the back of the paper so that single impurity-doped atom 66 now are semiconductor regions of substantial sizes. On the other hand, each of the semiconductor regions 62, 63, 64, 65, . . . may be only single atomic layers of p-type or n-type semiconductor material. Ion-implanted or atomic tweezer-picked chains or arrays of insulating material atoms 69 and doped atoms 66 may form the required single atomic layers 61, 61′, 61″, . . . . As shown above, atomic layers of various materials have been formed. The semiconductor regions, reduced to single atomic layers, may even be reduced in widths to be single atoms wide. The solid optoelectric device then reaches an ultimate miniaturization. Still, the performance of the individual components will remain unaffected. The atomic tweezer-formed semiconductor lines or regions 62, 63, 64, and 65, together with the mixes insulator and doped semiconductor chains 61, 61′, 61″, . . . form light-sensing or light-detecting devices possibly only three or four atoms wide.

Devices with more than four layers or regions 62-63-64-65 are also possible, giving three-dimensional sensing with the three electrode pairs 67-68, 67′-68′, and 67″-68″. The photon from laser or other light may also strike the device in all directions and not necessarily horizontally from the left only. Still, the one-dimensional (1-D), two-dimensional (2-D, and three-dimensional (3-D) light-monitoring devices are equally useful because all the variables including dimensions, impact angles, distances are known or predetermined.

By changing the thickness of the layers 62 or 63, or both, to control the distance the photon-generated carriers must travel before getting through the gate at the doped silicon atom 66, the sensitivity of the this optical reading, light sensing device may be desirably regulated.

The impact of a single photon on the device of FIG. 6 generates at lest two complementary electrical signals even in a single semiconductor chain or panel such as 61, 61′, 61′″, and 61′″. These two signals confirm each other greatly enhancing the accuracy and reliability of the monitored results. This is especially important in telecommunication where no error is tolerable whether handling data, sound, or image.

If the light first strikes into the n-type region 63, similar reasoning applies with the following exceptions: 1) of the photon-generated electron-hole pair, the hole is instantly recombined in situ with the closest electron abundantly supplied in the n-type region 63. The freed hole cannot move leftward into region 62 because of the reversed PN junction at the impurity-doped atom 66, and must move rightward into region 64; and 2) the external positive electrode 67′ is at the front of the region 64, while the external negative electrode 68″ is at the back of the region 63, so that the freed electrons drift toward the front while the freed holes drift toward the back in region 63.

The device of FIG. 6 has a next-to-the-bottom row of three impurity atoms 66. These three atoms 66 and the intervening semiconductor material regions 62, 63, 64, and 65, alone, can already form a one-dimensional light-monitoring device, for horizontal light monitoring, as shown, or for vertical light monitoring if the device is turned 90 degrees so that the three impurity-doped atoms 66 are aligned vertically rather than horizontally.

A diode can also be formed if the atoms are, instead of being n-type, p-type having only three electrons on each atom. Similar reasoning for the operational performance of the device used above also applies here.

If both regions 62 and 63 are of the same conductivity type, such as p-type, while the impurity-doped atom 66 is of the opposite type, e.g., an n-type dopant atom each with five electrons (or an extra electron compared to silicon) per atom, then a pnp transistor forms. One-dimensional, 2-D, and 3-D transistor arrays can be similarly formed.

Even devices with multiple vertical layers can also be designed and electrically connected by vertical, long but narrow trenches, grooves, or holes with aspect or length/size ratio of over three or five, as shown in the vertical grooves 43 in FIG. 4 of Li's '300 application.

As an optical reader, the device of FIG. 6 has sensor components each having a size comparable to the side of two impurity-doped atoms 66, one for forming the PN junction and the other for insulation. Each sensor component then has a size of the order of 5 to 9 angstroms. The atomically thin, perfectly flexible optical reader panel or array therefore can have up to 2,000×2,000 pixels per square micron. A one-micron optical fiber having a square array area if 0.707×0.707=0.5 square microns in cross-sectional area may still contain up to 2 million atomic light detectors. These optoelectrical devices are especially suited for modern optical telecommunications.

Replacing the doped silicon atom 66 by a semiconductor atom or molecule such as Ge (in Si), InP, GaAs, diamond, SiC, ferromagnetic, piezoelectric, or ceramic superconductor provides totally new generations of solid state devices of possibly far superior device performances and reliability.

Li's U.S. Pat. No. 4,690,714 also gives 3-D optoelectrical devices But the '714 patent and this invention are patentably different because: 1) The '714 devices generally have component sizes of 1 to 12 microns, certainly not several or even single atom sizes, or orders of magnitude larger; 2) The '714 devices do not have single-atom or single-molecule PN junctions, and are not single carrier, single-hole, single-electron, or single-photon devices. The photon-generated carriers such as holes and electrons are simultaneously pushed through the PN junction not one at a time, but many through the same doped atom PN junctions 56. These signal carriers are not monitored one at a time, as in the device of this invention; 3) While it is possible in the '714 devices to be smaller than 1 or 2 microns by, e.g., splat cooling, the smaller components would loss size and shape uniformity and even crystallinity, and become useless; and 4) The location and size of the components are not accurate to fractional microns, and certainly not atomic sizes.

It is recognized that the more complicated the device materials and production process, the lower the yield and the higher the final cost. Also, to achieve submicron accuracy, thermal expansion and contraction must be controlled and compensated in all directions, during gate placement, oxide reflow, and cooling.

As shown above, the gate layer 44 is the most critical part of the MOS or CIS devices. Further, serious problems still exist. Some of the prior patented techniques are useful here to improve the new gate layer. Specifically, Li in U.S. Pat. Nos. 3,430,109 and 3,585,714 disclosed that a rounded or curved insulating oxide material groove (FIG. 2) lessens the splitting forces on the neighboring silicon material, because this insulating oxide material has a blunt, not a sharp, tip or bottom in, e.g., a V-notch. There is no notch effect. A centrally rounded silicon pocket also achieve symmetry so that there is no weaker side.

With rounding, the mismatch stresses between silicon and other conductive contacting metals, and the adjacent oxide or other gate layer vary more gradually, not abruptly, graded near the rounded or curved bottom, due to curvature effects. These stresses are smaller on a curved adjoining surface than on a flat adjoining surface.

When material A is physically attached, or chemically joined or bonded, to a material B at a flat interface, severe interfacial mismatch stresses must exist due to different temperatures, dynamic conditions, or volume changes in in-situ compound formation. Physical attachments are not reliable. Failures are also likely or possible due to deboning of materials; poor or loss of electrical contact; fracturing of the thinner and weaker material into many pieces; and peeling of the thicker but weakly bonded material. With flat interfaces, no mechanisms exist to relieve or reduce the mismatch stresses.

The situation is different with a rounded interface. Rounding provides one or more mechanisms of stress relief. Being very close to the critical PN junction, a flat bottom of the oxide insulating groove often causes mechanical and subsequent electrical failures. With a rounded bottom interface having zero bottom width, the stresses are zero in the lateral direction at the bottom. Also, stresses are minimum and symmetrically distributed when the rounded bottom is symmetrical with respect to a longitudinal bisecting plane thereof. Symmetrical stress distribution insures that failure can occur on either side. That is, there is no weaker side so that the entire device is stronger overall.

The new gate layer of the invention can be formed by laser fusion. The layer then have blunt and curved or rounded, with liquid-smooth surfaces due to atomic forces exhibited as surface tension. As shown below, fusion and solidification maximizes chemical purity, mechanical strength, crystallographic perfection, and even self-optimized, oriented grains for maximum strength and thermal or electrical conductance in a preselected preferred direction.

The laser remelted and resolidified gate or field layer can be an extremely thin layer with an atomically smooth bottom surface and no rough edges or sharp corners. It should be curved according to this invention. It may have a constant thickness across its lateral dimensions, except to terminate at zero thickness at its peripheral edges so that the thermal mismatch stresses between materials are also zero in directions normal to the thickness.

The new gate layer is not flat, but curved like a soft pancake in a bowl with a round bottom. The mismatch stresses are smaller on the curved pancake surface than if the pancake were flat. The horizontal mismatch stresses at the rounded bottom of the gate layer are minimal or zero.

Instead of being laser-formed, the gate layer 44 may be a thermally grown-in oxide or nitride, an ion-implanted oxide or nitride, an ion-implanted intrinsic semiconductor gate layer of Si, Ge, GaAs, InP, SiGe, or other semiconductor materials with very few uncompensated dopants to thereby behave like an intrinsic semiconductor layer or at least substantially insulating layer relative to the p-type substrate and n-type pockets. These layers are not only electronically relatively inert and insulating to make useful CIS devices, but also are unetched, uncut, and otherwise similarly unmodified. This condition preserves the as-formed metallurgical continuity.

Metallurgical continuity or, even better, atomically perfect and continuous fusion-bonding of the new gate layer to a substrate 41 below and the gate metal lead 45 above, provides reliably perfect contacts and device structure, continuity, and repeatability.

As shown Li's U.S. Pat. No. 5,874,175 patent, the silicon substrate, silicon pockets, and silicon oxide/nitride should be bonded with a nearly 100% dense, bonding region which is mechanically defect-free, with no visible microcracks at 1,000× magnification. The bonding interfaces should be liquid-diffusion graded to avoid high mismatch stress gradients thereat.

In contrast, CVD, PVD, and many other Solid-state layer forming processes involve only solid-diffusion, leading to at least five orders of magnitude steeper stress gradients. This is because liquid diffusion coefficients are universally about 10⁻⁴ cm²/sec while solid-state diffusion coefficients even at near the melting point are only about 10⁻¹⁴ cm²/sec.

Filling or depositing particles of silicon, oxide/nitride, organic substances, or other materials into microscopic grooves or trenches may also be unreliable. Even with perfect nucleation and without shadowing effect, packing of perfect spheres according to the closest-packing hexagonal or face-centered cubic structures gives a maximum density of only about 75%. The packed layers are mechanically weak and chemically contaminating to the microscopically close to the PN junction because the porous layers can “breathe” and are usually of non-pure materials.

The “Ceramic Composite” U.S. Pat. No. 5,874,175 discloses various ceramic bonding techniques to bond materials including oxidized metals and ceramics. In air, silicon is known to immediately form an oxidized surface layer of about 18 Angstroms in thickness. The disclosed techniques can produce reliable but very thin bond layers to metals or ceramics. Properly done, the bond strength can be more than the weaker of the two bonded materials A and B before bonding.

Generally, metals are the stronger material, and ceramics, oxides, silicides, or plastics the weaker materials. However, with selected bonding techniques, the weaker materials can be surface-strengthened to be even stronger than the unbonded material itself. These dissimilar material bonds are metallurgically perfect, without voids, cracks, and other crack-initiating defects visible at 1,000× magnification.

These bonds can also selectively withstand 500, 630, 800, or 950° C., sufficient for the bonded assemblies to withstand any subsequent device processing procedures or service requirements, even for SiC or diamond semiconductor devices. These bonded material regions are different in structure, mode of operation, and results from the usual chemical or physical deposits, filled-in organics, flowed-on polymers, and spun-on or painted-on oxides. In these later materials, there is inadequate, or even little, atom-to-atom bonds which make the deposits strong.

The above techniques for forming the gate layer can also be used for other parts of the CIS device. For example, extremely thin, curved field layers of CMOS devices can be similarly formed by, e.g., laser, to electrically isolate one semiconductor region to another. This will be disclosed in more detail later.

Besides mechanical strength problems, a non-perfectly bonded material layer with voids and microcracks gives problems of high leakage current, low breakdown voltage, and poor device performance, reproducibility, yield, reliability, and resistance to the ambient particularly as to moisture. Hence, the importance of perfect bonding in microelectronics is evident.

As indicated above, a flat, very thin gate layer can not remain intact after bonding, particularly when subjected to significant stresses and strains. The flat surface provides no stress or strain-relief mechanisms, and the very thin layer has little strength to withstand even minimal thermal, dynamic, or volume change mismatch stresses. The very thin flat layer must fracture into many pieces destroying not only its mechanical integrity but its useful electrical utility. The curvature here is necessary to provide a number of stress-relief mechanisms. Such a curved gate layer is preferably provided in the same laser processing step, as shown below.

Proper bonding of the gate layer to the substrate 41 below and metal lead 45 above insures stable and reliable electrical contacts. A gate layer perfectly bonded to the substrate material alone is still not sufficient. The gate layer must also be prepared by proper metallization on its top surface for perfect bonding thereto of the conductive gate electrode 45. The conductive gate electrode is formed of an electrically conducting material generally centered on the gate area to control flow of electronic carriers from the source semiconductor pocket to the drain pocket.

The top bonding of the gate layer is as equally important as the bottom bonding. The above-mentioned U.S. Pat. No. 5,874,175 bonding patent provides techniques for atomic engineering the oxide-silicon interface to achieve mechanical and electrical perfection and thermochemical stability, so that the bonding strength does not decrease with time during service, as often observed. High interfacial perfection not only enhances mechanical and thermochemical stability, but also device performance including enhanced and reproducible dielectric constants.

Useful interface atomic engineering techniques disclosed in the '175 patent include: replace failure-initiating oxide or silicon surface voids and microcracks with mechanical, thermal, and electrical strengtheners, material purification and dielectric enhancement, grain refinement and preferential orientation to facilitate thermal and electrical conduction, and functional composition grading to meet special service requirements. The laser processing can be designed to self-optimize to achieve these desirable qualities not available with other processing methods.

For example, unidirectional cooling produces columnar grain growth. The anisotropic grains in the bonded regions are highly beneficial to achieve bonds with preferred direction of mechanical strength and thermal or electrical conductivity. The bonded region also have refined and highly purified gate layer material, with unique, uniform and repeatable properties. The uniformity results because the columnar grain growth is from a liquid melt in which materials diffuse at a liquid diffusion rate of about 10⁻⁴ cm²/sec or about 10 orders of magnitude larger than many of the common layer-forming processing with only solid-state diffusion rates. Chemical composition profiling across the bonding interface, grain sizes, and mechanical properties are also more gradual, uniform, and reproducible.

Under unidirectional cooling and freezing processes in a direction normally of the gate layer, the dielectric material is purified according to the principles of normal freezing and William Pfann's unidirectional temperature-gradient zone melting (Wiley, New York, about 1950). These processes generally achieve orders of magnitude in material purity based on the segregation coefficient on the relevant alloy phase diagram.

A silicon melt containing either Fe or Co, for example, has a segregation coefficient of only 0.000,008. The silicon layer is therefore purified by over 125,000 times by simply directionally freezing once, or by over 15,600,000,000 times by directionally freezing twice. Similar purification results if the silicon dioxide layer is also melt-purified to achieve vastly improved dielectric constant.

Proper melting and freezing is by far the fastest, simplest, and most reproducible and cost-effective method to produce high-yielding, high-quality semiconductor devices. It is not coincidental that years ago the best transistors and diodes were made only by melt growth processes.

Applied to the gate layer formation, the melt growth process of the present invention also is the simplest, fastest, and most cost-effective method of reproducibly producing high-quality gate layers. Most specifically, the new gate layer material can be the purest, most defect-free, crystallographically perfect, uniform, with the thinnest but strongest grain or subgrain boundaries, and the exact desired dielectric constant otherwise impossible to obtain. The subgrains are also substantially uniform in width or size and height.

Integrated circuits of the invention must have atomic accuracy in shapes, sizes, spacings, and material properties. The circuits must be controlled and compensated in all directions. During the hundreds of IC processing steps including the critical gate placement, oxide formation, and exact cooling. The more impure the device materials and the more complicated the processing equipment and procedures, the lower the device yield and the higher the final device cost.

The formation of the new gate layer, particularly with a fast-acting laser, gives at least a multiple of the following important advantages:

1) The laser heating melts the gate layer material and smooths the top and the more critical bottom surfaces by an atomic surface-smoothing mechanism, i.e., atomic surface tension forces applied on a free melt surface. This achieves minimum roughness on both the top and bottom dielectric surfaces. As shown above, a smooth gate dielectric surface with very small channel length leads to improved transistor performance. Since silicon and SiO₂ differ significantly in thermal conductivities and surface reflectivity, a laser heating process must be designed as to pulse speed, power, and duration to melt preferably only a surface layer of SiO₂ without significantly affecting the underneath silicon substrate;

2) Solidification of the molten oxide gate layer material, sub-layer by sub-layer, from the bottom surface up purifies the gate layer material not only greatly reducing impurities, inclusions, stresses, defects, but improving insulation partly by purification. Most of the purification takes place precisely at the critical bottom surface facing the substrate. As shown, the first solidified sub-layer, closest to the substrate, has the most purified dielectric material;

3) Any substrate silicon top layer melted by the laser is also highly purified. For example, Fe, Co, Zn, Au, Cu, In, Bi, Ga, Al, As, Sb, Li, and B respectively have distribution coefficients in freezing silicon of 0.000008, 0.000008, 0.00001, 0.000025, 0.0004, 0.0004, 0.0007, 0.0080, 0.002, 0.023, 0.3, 0.01, and 0.8, according to CRC Handbook of Applied Engineering Science, Ed. R. E. Bolz and G. L. Tuve, Cleveland Ohio 1970, pp 206-207. The purification factors for this list of elements are, respectively, 125,000, 125,000, 100,000, 40,000, 2,500, 2,500, 1,428, 1,250, 500, 43.5, 3.33, and 1.25. Except for p-type dopants As, Sb, and B, a single freezing purification is generally sufficient. If not, the process may be repeated by pulse heating the resolidified layer to purify a second time to achieve combined purification factors of up to 15,625,000,000 times. Even a third or more time of freezing purification may be applied, especially with intrinsic silicon containing low-segregating dopants As, Sb, and B. The laser-melted and resolidified SiO₂ or other material gate layers also contain various undesired impurities as shown above. These impurities in the gate layer will be similarly removed by melting and resolidification;

4) While molten by laser heating, the gate layer material may be removed by laser evaporation or sputtering, leaving an extremely thin layer (e.g., 0.1 micron down to 1-2 atomic layers) of melt-refined material. The highly pure SiO₂ has very high dialectical constant should freeze into a concavely curved depression when looked from the top. This purified and refined gate layer has exceptional bottom smoothness and minimum microcracks, voids, inclusions, and stresses. As shown, the curvature minimizes mismatch strains and stresses due to thermal expansion, density differences, or volume expansion to form SiO₂ from Silicon;

5) Microsecond, nanosecond, picosecond, or even femtosecond pulsed laser heating instantly heats up a superficial top layer which splat cools. The bottom surface of the molten layer has an extremely short solidification cycle. Such fast solidification gives very little time for grain growth. Extremely fine grains with minimal grain boundaries therefore result. The fine grains again produce the desirable, smooth gate dielectric facing the substrate. Further, the purified and defect-free grain crystallites are oriented in the cooling direction normally of the local bottom gate layer surface. This orientation maximizes thermal and electrical conductivities in the most desirable direction. Note that the laser pulse heating is so fast that it can be designed to heat and melt refractory oxide (e.g., SiO₂ melting above 1,300° C.) without too much affecting the substrate silicon (melting at 1,430° C.);

6) The laser and other auxiliary heating systems can be automatically feed-back controlled according to Li's self-optimizing patents cited herein, so that the molten material optimally melts and freezes into solidified elongated grains or even single crystallites. These grains or crystallizes have extremely purified Si or SiO₂ dialectical materials. The SiO₂ crystallites consist of extremely purified dialectical material and have very thin, mechanically perfect grain or subgrain forming excellent gate layer materials. These crystallites have the lowest thermal and electrical resistivities because they are highly purified and the intervening subgrain boundaries are the thinnest;

7) By flexing, the thin curved gate layer eliminates thermal and dynamic mismatch stresses and strains providing a perfect gate layer without microcracks which cause unwanted instabilities, boron penetrations, and leakage currents; and

8) The laser heating produces a molten gate material which promotes an intimate, metallurgical liquid-diffusion graded bond atomically matching in dimensions, continuously across the entire contact interface region, without thermally and electrically insulating voids or microcracks visible at a magnification of over 1000× times. Such good bonds insure that the gate layer intimately bonds to, or tenaciously stays in place onto, the substrate to guarantee reliably good electrical contacts.

As shown above, melt growth greatly purifies and strengthens the frozen materials, forms crystallites of uniform shapes, sizes, lengths, and spacings, and even with very good crystallinity and microstructure. In fact, each of the melt-grown grains or subgrains may be perfect single crystallites with controllable orientation for specific electrical, thermal, optical, or other purposes. This bonding of the gate layer to the substrate generates a liquid-diffusion graded bonding interfacial region there between to reduce the thermal stress gradient across the interfacial region and to minimize stress-induced carrier mobilities changes.

A better bonding technique is possible by using a solution metallizing and bonding method given in, e.g., U.S. Pat. No. 5,874,175, without appreciably increasing the gate layer thickness. The solution metallizing method has already been successful to join practically all ceramics including silicon dioxide, silicon nitride, silicon carbide, alumina, zirconia, and diamond. A perfectly bonded gate layer enhances the circuit yield, performance, stability, reliability, and life.

Gate layers on present MOS devices are already quite useful, except as to reliability and reproducibility in very fine devices with extremely thin gate layers. Hence, not all the beneficial qualities produced by the new laser processing method, i.e., atomically surface-smoothed, purified material, extremely thin gate layer; grain-refinement, grain orientation, and perfect bonding need all be present in any specific IC processing. In any case, one should use as few processing steps as possible if fairly good competitive yield is already obtained with as few of the new features of the invention.

Other improved material processing methods may also be used instead of laser. For example, focused electronic beam may be also used for the heating. Laser, electron, ion, proton, and other energetic argon particle bombardment may be used to remove material for forming the depression with curved surfaces or walls. Chemical-mechanical polishing (CMP) methods are also useful also to form some of the curved depressions or to produce the curved, extremely thin gate layers.

Ion implantation can produce ultra-fine regions of insulating, conducting, and semiconducting materials, even completely inside the semiconductor. In particular, multiple ion-implantation steps may be employed to introduce p-type or n-type dopants, oxygen, nitrogen, and other foreign atoms precisely into the silicon substrate, in precise quantities and chemical profiling, shapes, sizes, and spacings. The required implanting voltage may vary from 1 megavolt, 100 kilovolts, 10 kilovolts, down to less than 1 kilovolt. Even under an implanting voltage of one megavolt, oxygen and nitrogen can be introduced into silicon host to a depth of 1.7+/−0.13 and 1.87+/−0.12 microns, respectively. That is, the accuracy of the implanting depth is already about 0.12 to 0.13 microns some 30 years ago. Smaller implanting voltages used nowadays gives even greater implanting accuracies.

Properly focused laser beam can be 20-40% smaller than gate gap width but still with enough power to remove the molten gate layer material to produce a concave (looking from the top) groove or depression covered with precisely the required amount of thin gate layer material of, e.g., 3-40 Angstroms. It has been found that neutralizing many of the photons in the laser beam facilitates the focusing to a smaller size. Similarly, ion beams may be neutralized by electrons to achieve similar results.

Precision silicon removal by laser also achieves two unique effects: a) thin layers of even brittle ceramic materials, such as SiO₂, become flexible and can tolerate much greater thermal mismatch stresses and strains without microcracking or void formation, thereby maintaining the exacting desired properties of the gate layer material; and b) a concave or any concavely curved groove surface can resist thermal mismatch stresses by neutralizing the mismatch strains, through a curvature-related stress-relieving effect, as shown above and later.

A rounded insulating gate material groove lessens the splitting forces on the underneath silicon substrate layer because the SiO₂ groove bottom has a blunt, rather than a sharp crack-initiating tip or bottom. There is therefore no notch effect. The mismatch stresses between silicon substrate and the insulating gate layer vary gradually, not abruptly, near the rounded bottom, due to curvature effects These stresses are smaller on a curved adjoining surface than on a flat adjoining surface. In particular, the stresses are zero in the lateral direction at the bottom if the bottom has a zero width, and minimum and symmetrically distributed when the rounded bottom is symmetrical with respect to a longitudinal bisecting plane thereof. The zero bottom width and symmetrical depression shape are made by proper laser focusing procedures.

The laser melting of the gate layer provides an atomic surface-smoothing process to achieve a liquid-smooth surface on the lower surface of the gate layer facing the substrate. When molten, the gate layer material has atomic surface tension forces on the melt surface to produce the liquid-flat, lower gate layer surface.

The laser beam can be focused to such a beam size with such a power density profile to remove a selected part of the melt materials by material ejection or evaporation thereby forming a concave depression containing the remaining melt material. Rapid or splat cooling (over 10⁶° C. per second) of the remaining molten gate material produces ultra-fine solidifying grains or subgrains further smoothing the lower gate layer surface. In addition, progressively solidifying the melt material from the bottom up purifies the solidifying melt material, according to the relevant phase diagram of silicon and the specific gate layer material. The most material purification occurs precisely at the lowest or first-to-freeze layer closest to the substrate to thereby have the best gate material properties including the highest electrical insulation properties thereat.

Generally, a single melting/solidification/purification is adequate. When needed, remelting the solidified gate material and repurifying the remelted gate material may be used to achieve further material purification for additional improvement in the electrical insulation, mechanical, chemical, and other properties of the gate layer. The laser melting and resolidification process also gives a gate layer material which is thoroughly aged by liquid diffusion. This gate material is fully compatible with silicon at the interface, mechanically and thermochemically, and can tolerate severe further silicon processing and temperature cycling.

The focused laser beam additionally gives a curved depression designed to reduce substantially the thermal mismatch stresses through a curvature-related stress-relief mechanism. Generally, the gate layer should have a concave shape when looked from the top, with a radius of curvature of less than 0.5 to 1.0 microns, or less than fifty times thickness of the gate layer.

An alternate method for forming a thin, flexible, liquid-smooth, and curved gate layer is as follows. First smooth the top surfaces of both the source and drain regions by additional precision chemical etch of CMP with automatic real-time feed-back control. Dopants are very superficially implanted into these regions in very high concentrations. A very superficial top layer of each smoothed surface may be further smoothed by fast laser or microwave heating to above 1,000° C. for less than several seconds, or even to the point of superficial liquidisation and liquid smoothing.

Such very rapid superficial heating, applied for a very brief time particularly during heating up and cooling down, achieves additional benefits in producing the highly desired, very shallow but high activated (or dopant-concentrated and low-resistivity) junction rather than a longer anneal at a lower temperature. At such high spike heating rates, the common phase diagrams, which assume that all contacting component materials are always at complete thermal equilibrium, no longer apply or even relevant. New dynamic phase diagrams must be used. Dopant concentration much greater than the thermodynamic-equilibrium values are thus obtainable—a distinct plus for advanced devices.

The extra thin, flexible, and curved gate layer is then formed on the very smooth top surfaces of the source and drain regions. Heating may be required for better bonding adhesion. Again, very superficial heating by fast laser pulses, microwave, or both, are used to heat or even melt the very bottom surface of the gate layer. Athermal shock bonding or pressurized welding of the liquid-smooth, curved gate layer onto the top surfaces, with or without the addition of microwave or laser pulse heating.

The gate layer should be so thin as to be flexible and to relieve thermal mismatch stresses through flexing thereof. It should be no more than about 0.1 micron thick. One to three atomic layers may be the minimum. The gate layer should be of a size to make the gate width very small, such as less than 0.30, 0.20, or 0.10, 0.01, down to 0.001 microns, to thereby reduce the thermal mismatch stresses. These stresses are proportional to the gate width.

In one preferred embodiment, the gate layer has substantially the same material as materials of both the pockets and the substrate, and consists essentially of silicon, with up to less than about 10 or 5 ppm of impurities. Practically all the impurities are compensated, leaving few free electrons or holes to conduct electricity. The gate layer is thus practically electrically insulating. Because of practically the same chemical composition, the gate layer, the substrate, the pockets, and even the doped silicon gate lead all have substantially the same coefficient of thermal expansion minimizing thermal mismatch stresses.

All the essential device materials in these new devices also have practically the same density, minimizing dynamic stresses due to vibrations, impacts, high accelerations and decelerations, and centrifugal forces and accelerations. This can be seen as follows: Silicon has a density of 2.33 g/cc. Dopants such as P, B, As, Sb, Al, . . . are unimportant because of their insignificant ppm or ppb ranges.

Silicon dioxide and silicon nitride have densities of 2.33 and 3.17, not much different from that of silicon. But not Al, Ge, Ni, Cu, Au, Ag, Ta, Ti, Hf, W and Zr materials used for contacts and interconnects. These contact materials have densities of 2.70, 5.32, 8.90, 8.96, 19.3, 10.5, 16.7, 4.54, 13.3, 19.3, and 6.51 g/cc, respectively. When the semiconductor circuit is accelerating at 1 gravity level (G), there is a differential inertia force of 2.70−2.33=0.37, 2.99, 6.57, 6.63, 17.0, 8.17, 14.37, 2.17, 11.0, 18.0, and 4.14 G acting on the Si-metal assembly to break it up by tension or shear. The G-levels to cause tensile failures in the silicon or silicon-metal interface can therefore be predicted by using the relevant tensile or shear strength of silicon relative to that of the particular metal.

As an example, at 10 G, both W and Au with the same density of 19.3 are exerting on the Si—W or Si—Au interface to tear it apart with a force of 18.0×10×980=186,000 dynes, respectively. The bond between silicon and other contacting metals in the silicon circuit is often merely physical and very weak. Yet, this bond, which critically governs the performance and reliability of the integrated circuits, can easily break up on conventional circuits under the acceleration or centrifugal forces.

The new gate and field layers of this invention, particularly when metallized and bonded according to U.S. Pat. No. 5,874,175, uniformly or 100% dense with no voids or cracks, ensuring their permanent, intimate bonding reliably to the substrate. These new gate layers are therefore resistant to environmental conditions particularly G forces occurring during shock, impact, vibration, and rapid acceleration and centrifugal forces.

Si (density 2.33) integrated circuits containing only intrinsic Si as insulators, semiconductors, or conductors are the most resistant circuits to dynamic forces. This is because the two components materials, Si and intrinsic Si, have practically the same density differing at most by only ppm due to the ppm doping impurities. Si circuits containing silicon dioxide (2.334) insulators have density differences of only 0.004 g/cc or 0.172%; while Si circuits containing Al (2.70) conductors have a density difference of less than 16%. Silicon circuits containing the nitride (3.17), Ti (4.54), Ge (5.32), Zr (6.51), gold (19.3) and tungsten (19.3) have a density difference between its component materials of less than 36.1%, 94.8%, 129%, 180%, 728%, and 728%, respectively.

Using a single silicon material for the p-type pocket, n-type pocket, isolating region, gate layer and gate lead materials achieves the best dynamic mismatch stresses and strains. The resultant circuits are extremely resistant to environmental impacts, vibrations, and large or rapid accelerations and decelerations. Even using materials with densities of no more than 10, i.e., Al, Cu, Ge, Ti, Hf, and Zr, will significantly improve the device's resistance to dynamic mismatch strains and stresses. On the other hand, materials such as W or Au should be eliminated for uses as device materials, if high acceleration forces are likely.

Any dopant changes in the pockets and substrate material due to the laser processing may be corrected by ion implantation of the proper dopants such as P, Sb, As for n-type and Al and B for p-type silicon. The implanting voltage should be no more than a value selected form the group consisting of 100 kilovolts, 10 kilovolts, and 1 kilovolt. Also, instead of intrinsic silicon, doped but nearly fully compensated silicon may also be used for replacement of the gate material.

In fully compensated silicon, the n-type dopants and p-type dopants differ in dopant concentrations by no more than several ppb or less, both the electron and valence bands are nearly completely filled, allowing very few carriers to move therein, thereby also providing a substantially electrically insulating material, particularly when in comparison to the conventional p-type substrate and n-type doped pockets.

In a similar way, a new field layer electrically isolating two regions of the same or different conductivity type in an integrated circuit can also be beneficially made of a thin, flexible electrically isolating material. Here, the semiconductor integrated circuit comprises: a semiconductor substrate of a first conductivity type, and a semiconductor pocket of the opposite conductivity type on top of the substrate thereby forming a PN junction region at where the semiconductor pocket contacts the substrate. A field layer of a substantially electrically insulating material is formed of a substantially constant thickness except at its bottom. At this bottom, the field layer is rounded and has zero bottom thickness or width (i.e., one atom thick or wide as shown by the field layer 47 in FIG. 4), according to the principle disclosed in U.S. Pat. No. 3,585,714.

FIG. 4 also shows the new curved, possibly atomically thin, gate layer 44 below the conductive gate lead 45. The new field layer starts at a top surface of the surrounding semiconductor material pockets 46, and extends substantially vertically downward pass the entire pocket depth, i.e., through the n-type region 42 into the substrate 41. This field layer is sufficiently deep to divide the pocket into two separate electrically isolated regions. Together with the PN junctions, this field layer physically separates and electrically insulates the two separated regions 42 of the pocket from each other.

The field layer also has such a material in such a structure as to be sufficiently yieldable to minimize thermal mismatch stresses between various contacting materials of the substrate 41 and separated regions of the pockets 46. In this way, the performance and reliability of the semiconductor circuit device is significantly improved.

Since the field layer 47 may be only one to several intrinsic silicon atoms or SiO₂ molecules thick, it occupies practically zero chip real estate. At least, it is hundreds or thousands times thinner than the conventional oxide isolating regions, such as the regions 41a through 41d in FIG. 1 of Peltzer's U.S. Pat. No. 3,648,125 patent.

Li's prior solid-state device patents show the use of oxide isolating grooves which have zero bottom widths avoiding the flat portions on prior-art devices and enhancing device miniaturization. Except for a layer thickness of one to several atomic or molecular layers, the new field isolating layer 47 or 51 of this invention practically eliminate the entire space for the common field isolating groove or layer. This new design of the field layer thus saves much chip real estate thereby helping to achieve the most in device miniaturization.

The new field layer 47 of FIG. 4 has a curved shape on a horizontal cross-section, as shown in FIG. 5, to reduce substantially the thermal mismatch stresses. Reduced stresses maintain material integrity of the thin and fragile field layer. Except for its bottom, the entire field layer has a thickness of 20 down to one or two atomic layers.

The silicon pocket regions 46 have thicknesses of from less than 10 to 1,200 Angstroms. The thermal mismatch strain and stress, being proportional to a length, is therefore several to many times greater and more critical in the horizontal direction than in the vertical direction for the thin-film devices of this invention. On a horizontal cross-sectional plane, the new field layer preferably has a single circular curve or a multiple sinusoidal curves to best combat thermal mismatch stresses and strains, as shown in FIG. 5.

The new field layer 51 in FIG. 5 has a curved shape with a radius of curvature of less than 10 angstroms to 1.0 microns. Being thin, the field layer can flex and yield to relieve applied stresses thereby maintaining its material integrity and electrical utility.

It is desirable to have a thin and flexible, curved or rounded field layer 51. Because of the extremely thin walls, curvatures in the vertical cross-sections are difficult to form. Curvatures on a horizontal cross-section are therefore used instead. This is shown in FIG. 5 where a top view of a square CIS of unit size, such as 0.1 micron square. This device has a perimeter of multiple insulating material wall of oxide or nitride material 51 ion-implanted into, e.g., a silicon substrate.

FIG. 5 shows a generally square-shaped CIS silicon device. Each device has four oxide isolating grooves or walls 51-54 to enclose the CIS device. Each of the grooves has a wall thickness of from 20 down to one or two intrinsic silicon atomic layers or SiO₂ molecules occupying negligible chip real estate. Practically all the chip real estate is used for the actual circuit components. The top isolating groove or insulating wall AB 51 is a straight wall of unit length (e.g., 0.1 micron). The right circular isolating groove BC 52 consists of one-quarter of a circle of radius of 0.0707 microns (i.e., 0.1/square root of 2), with an 90-degree arc giving a curved wall length of 0.178 microns. The bottom half circular isolating groove or insulating wall CD 53 consists of one-half of a circular wall of radius of 0.500 microns, with a 180-degree arc length of 0.157 microns. The left isolating groove or insulating wall DA 54 is a 360-degree full wave with a radius of curvature of 0.25 microns, with an arc length of 0.157 microns.

FIG. 5 shows new mechanisms to relieve the unavoidable thermal mismatch strain between the silicon substrate and the generally square-shaped device thereon. This strain relief is due to the curvature of the insulating walls or field layers 51-54. The small arc length for each side is 1=r×A where r is the radius of curvature and A the subtended arc angle. When thermal mismatch strain occurs, the small arc length l for each side changes by delta l to neutralize the strain as follows: delta l=delta (A×r)=r×delta A+A×delta r. That is, at least one of the radius r, arc angle A, and arc length can automatically change.

A new mechanisms of stress and strain relief therefore results through automatic changes in radius of curvature r, subtended arc angle A, and arc length l. Further, all these changes delta l delta A, and delta l must be in directions to reduce, but never to intensify, the strain. This is because all these changes merely respond to the mismatch strain, and not the cause or initiator of the thermal strains. In addition, the changes in l, r, and A automatically stops when the residual mismatch strain is so reduced by the changing l, r, and A that it can be tolerated in the thin insulating oxide wall of the device.

FIG. 5 further shows that for the same unit edge length on each of the four sides of the generally square circuit component, the top straight side, 51 or AB, is the least capable of withstanding mismatch strains because it is planar and not curved and has no r and A to change. Next comes the right side, 52 or BC, which has the least arc length with minimal capabilities of changing l, r, or A. The left side, 54 or DA, has the longest arc length. Even for the same linear side length DA, arc angle beta, the multiple arcs on the left side provide more opportunities to change the six variables on l, r, or A and, finally, the mismatch strain, on side curved 54 than on the curved sides 53 and 52.

The thermal expansion coefficient of silicon substrate is a1=0.0000027 per ° C., while that of the silicon dioxide insulating wall is a2=0.0000005 per ° C. The difference is 0.0000022 per ° C. Hence, raising or lowering the silicon CIS by a mere produces a thermal strain of 0.0000022 per unit length of the component. Assuming only the Young's Modulus of silicon is operative at 16,000,000 psi because of extreme thinness of the silicon dioxide insulating layer, a 1, 100, and 300° C. change in temperature in a device processing step or service condition then generates a thermal mismatch stress of 35.2, 3,520, and 10,600 pounds. A tensile strength of 7,000 psi for silicon dioxide is taken in the above calculations, according to Handbook of Applied Engineering Science, Eds. R. Bolf and G. L. Tieve, Chemical Rubber Co., Cleveland, Ohio, 1970, p 138.

Hence, a circuit processing step involving a temperature change of mere 199° C. can fail the thin, straight oxide layer on the top device edge or boundary AB or 51 of the FIG. 5 device. Yet practically all conventional devices have straight edges such as 51.

On the other three edges BC, CD, and DA, the conditions are more favorable. There are curvature-related strain and stress-relief taking place as described above and elsewhere and in Li's patents, e.g., Li's U.S. Pat. No. 4,946,800. A particularly useful curvature effect can be seen as follows when applied onto the wall BC or side 52. This insulating circular wall has a radius of curvature of 0.0707 microns, and extends over an arc angle of 90° C. Any small arc on this wall, e.g., EF, thermally expands less than the underneath silicon substrate.

For every ° C. increase in temperature, a thermal mismatch strain of 0.0000022 occurs, as shown above. If the wall BC or 52 were straight, as in wall AB or 51, a thermal mismatch stress arises tending to fracture the thin oxide wall. With a curved field oxide insulating wall BC of this invention, the thermal mismatch strain and stress are relieved through curvature-related relief mechanisms partly explained above and partly in U.S. Pat. No. 4,946,800.

During in-situ formation of silicon dioxide from silicon via thermal oxidation or ion implantation, the silicon host material undergoes a volume expansion corresponding to a linear expansion of 29.2%. See U.S. Pat. No. 4,946,800, col. 5, lines 57-67. Similar in-situ formation of silicon nitride gives a linear expansion of only 4.3%, or 6.79 times smaller than that during oxide formation. Hence, in-situ formation from silicon of silicon nitride produces only 14.7% of the mismatch volume strain and stress of those during similar in-situ formation of silicon dioxide, if silicon oxide and nitride have comparable coefficients of thermal expansion.

This huge difference at least partly explains the beneficial use of the nitride in place of at least some of the oxide in the formation of the gate layer or field insulating layer. The nitride, or mixed nitride and oxide is, thus preferred over oxide in forming the new gate or field insulating layers in the present invention. For similar reasons, the nitride or mixed nitride and oxide should also have better thermal resistances than the pure oxide.

As indicated above, the present oxide gate layers are very useful. They fail only when extremely thin oxide films are used, mainly due to fractures and leakage or tunneling currents. They also often don't stay in place or stick to the substrate. The use of extremely and uniformly thin bowl-shaped gate layer with a curved boundary in combination with a symmetrical zero-bottomed width should significantly overcome the high-stress and microcracking problems. A uniformly defect-free gate layer then forms to prevent or minimizing boron penetration, leakage current, and tunneling electrons from the gate to the substrate through the gate oxide.

Merely making the new ultra-thin but perfect, curved gate (and field) layers with minimum channel length or gap size (below 20 or 10 nm) may be already sufficient to improve device performance and reliability, even without the other possible features of this invention such as atomically liquid-smoothed gate bottom layer of purified, oriented, strengthened or even single-crystalline gate layer material grains as described above.

Making semiconductor integrated circuits is not to achieve scientific perfection, but to rapidly and cost-effectively produce competitively good and useful circuits with simple and the minimum processing steps using the least number of processing equipment, processing steps, and device materials. As a matter of fact, simple minimum processing steps and the least number of processing equipment and device materials invariably lead to higher yield and lower cost, as shown above.

Further, knowing what the desired shape, size, and thickness of the gate layer, methods other than laser heating can be used to achieve at least some of the same results. For example, starting with a wafer of an intrinsic, p-type, or n-type silicon, one can ion implant dopants, oxygen, and nitrogen to form the needed n-type region or pocket, p-type region or pocket, PN junction, and oxide or nitride grooves or layers to submicron, nm, or angstrom precisions in thickness, location, dopant or oxide concentration profiles, and conductivity or resistivity characteristics. With the same starting wafer, thermal diffusion may also be used to achieve similar, but not exactly the same, results.

The U.S. Pat. No. 3,585,714 patent and application Ser. No. 154,300 disclose material-removing techniques, with automatic feed-back control, to form the microscopically precise grooves or regions. “Microscopic” in these prior patents means that dimensions, radii of curvatures, thickness, and their accuracies are in the range of 1 or 2 microns. But with the advances of materials science in the past 35 years, this invention reduces these dimensions and accuracies to 0.5 microns down to about 3 Angstroms or 1 atomic layer.

These material-removing techniques comprises mechanical, chemical, chemical-mechanical-polishing (CMP), and energetic or high-velocity particles bombardment with photons, electrons, ions, and protons. These methods are useful in the practice of this invention in the formation of extremely thin gate layers and tiny isolating grooves of any reasonable shape and size, at specific locations and accurate to submicrons down to about 3 angstroms or 1 atomic layer. In particular, the groove shapes may range from cylindrical, elliptical, and spherical, and conical (U.S. Pat. No. 3,585,714, col. 3, lines 57-58) in vertical, horizontal (application Ser. No. 154,300 FIG. 4), or inclined forms, and with flat, spherical, rounded, or conical bottoms. These disclosures anticipate the December 1973 IEEE paper by Sanders et al on V-grooves which are conical grooves first disclosed in Li's U.S. Pat. No. 3,430,109 patent in September 1965.

Foreign materials, such as O, N, Ge, Si, Ga, B, P, As, CVD Black Diamond, florinated silicate glass (FSG) with k=3.6, and spun on low-k (k=2.7) SiLK organic material from Dow Chemical in use at IBM may be introduced for selected device applications into the newly formed grooves, or other selected locations by various processes including ion implantation (O, N, Ge, Si, Ga, B, P, and As), CVD, physical vapor deposition (PVD), chemical vapor deposition (CVD), spraying, spinning on, plating, . . . . Some of these added-on material may even form conductive (Al, Cu, Au, Pt, Pd) regions, layers, or leads in, e.g., semiconductors, 9-nm flash memory tunnel-oxide layer, silicon on insulator (SOI) region alongside bulk Si, and superconductor, magnetic, and optoelectric devices. The conductive materials may be metals such as Al, Cu, W, Ta, Hf, Zr, and Ti. The material of the isolating regions, grooves, or high-k or low-k dielectric thin films may vary from oxides (of Si, Ge, AL, Hf, Zr, Ta, Ti), nitrides (of Si, Ti, Al), polysilicon, glass, silicides (Ti, Ta, Zr, Hf, Co, and Ni), and silicates (Hf, Zr).

In the formation of the new curved extra-thin gate layers, the silicon substrate may be, for example: 1) planarized with CMP process; 2) grooved with spherical, conical, or V-shaped with rounded cylindrical, or flat bottoms. See U.S. Pat. No. 3,585,714:3/67-56, and 9/6 and 16-17). See mechanical polishers used to form a horizontal concave spherical bowl or vertical deep and narrow hole; and 3) superficially surface nitrided and/or oxidized with ion-implantation.

The oxidation or nitridation can be controlled with precision feed-back control to achieve exact ultra-sensitive film thickness control to angstroms. The feed-back control preferably is aided by real-time sensing with one or more precision electro-optic sensors to sense color, reflectivity, emissivity, surface smoothness, and other thin-film optical characteristics. Softwares are available to fuse the sensed data in real time to achieve ultra-precision in the control of film thickness and optical, physical, and chemical properties.

The field insulating layer of the invention can be extremely thin, from 0.5 microns through lm down to 3 Angstroms (i.e., one atomic layer). In fact, the thinner the better. A single atomic layer often suffices. Even randomly or intentionally added impurity atoms are useful to form single-electron devices (SED), single-hole device (SHD), or single-photon device (SPD). But because of the extreme thinness, the field layer is only curved only in one direction, i.e., horizontally. To make this layer curved vertically appears to be hardly practical at present.

The gate insulating layer of the invention can also be extremely thin, also from 0.5 microns through 1 nm, down to 3 Angstroms (i.e., 1 atomic layer). In fact, in many applications the thinner the better, particularly as to flexibility, integrity, and reliability. A single atomic or molecular layer often is the most useful. Because of this thinness, the field layer is only curved only in one direction, i.e., horizontally, not vertically.

The new field insulation layer is preferably formed by ion implantation. As shown below, a wave form consisting preferably of multiple sinusoidal curved segments is more effective than both straight line and a simpler curved structures. The multiply wavy or curved structures can be formed by having a wavy movement of the substrate relative to the ion beam. Besides forming oxide or nitride structures, ion-implanting oxygen or nitrogen may also forms insulating mixed oxide and nitride compounds other than of silicon or silicon oxide. Ion implantation may also be used to implant antidopants to compensate existing dopants for forming other useful, relatively intrinsic insulating materials for device applications. In these applications, p-type doping ions are implanted into n-type regions, while n-type doping ions are implanted into p-type regions to compensate the existing dopants leaving few free electron or hole carriers to improve electrical insulation.

As shown above, under an implanting voltage of one megavolt, oxygen and nitrogen ions can be introduced into silicon host to a depth of 1.7+/−0.13 and 1.87+/−0.12 microns, respectively. For modern CIS, 1.87 micron field insulating walls are sufficiently deep for practically all applications. Further, the implanted layer can be less than submicrons (e.g., down to a few atomic layers), have very sharp boundaries (to minimize chip estate), and can be accurate even to 3 Angstroms in depth, lateral dimensions, accuracies, and chemical composition profiles, as shown elsewhere.

Preferably, the field layer is made of a material having substantially the same chemical composition and, therefore, coefficient of thermal expansion as those of both the pocket and the substrate. This reduces thermal mismatch strains and stresses. Ideally, the field layer and pockets, and even the substrate, are of substantially the same density and material composition, except for several parts per million of foreign impurities, containing less than 20 down to several parts per million of uncompensated dopant impurity atoms.

To achieve full isolation, the insulating field groove must extend from the pocket into the silicon substrate layer. The groove bottom has a blunt, rather than a sharp, tip or bottom. There is no notch effect. The mismatch stresses between silicon and the insulating field layer vary gradually, not abruptly, near the rounded bottom, due to curvature effects. These stresses are smaller on a curved adjoining surface than on a flat adjoining surface, due to the new curvature-related strain-relief mechanism shown above. The mismatch stresses are zero in the lateral direction at the bottom if the bottom has a zero width. These mismatch stresses are minimal and symmetrically distributed when the rounded bottom is symmetrical with respect to a longitudinal bisecting plane thereof. Symmetrical stress distribution insures that both the left and right side of the device components fail with equal probability giving an overall enhanced device reliability. Proper focused laser processing produces both the zero bottom width and symmetrical depression shape.

The insulating chain or panel 61, 61′, 61″, . . . may not be atomic but has appreciable width in a direction normally of the paper in FIG. 6, and extends horizontally toward the back of the paper so that single-impurity-doped atom 66 now are semiconductor regions of substantial sizes. On the other hand, each of the semiconductor regions 62, 63, 64, 65, . . . may be only single atomic layers of p-type or n-type semiconductor materials. Ion-implanted or atomic tweezer-picked chains or arrays of insulating material atoms 69 and doped atoms 66 may form the required single atomic layers 61, 61′, 61″, . . . As shown above, atomic layers of various materials have been formed. The semiconductor regions can be reduced to single atomic layers, and may even be reduced in widths to be single atoms wide.

The atomic tweezer-formed semiconductor lines or regions 62, 63, 64, and 65, together with the mixed insulator and doped semiconductor chains 61, 61′, 61″, . . . for not only light-sensing or light detecting devices possibly down to only three or four atoms wide, but also CMOS device of FIG. 4 useful for, e.g., logic processors or memories.

The invented processes use the minimum number of device materials processed in simple processing equipment with simple procedures. Skilled persons in the art recognize that the more complicated the device materials and production process, the lowers the device yield but higher final cost. The processes must also control the thermal expansion and contraction in all directions and during all processing steps.

The solid state devices of this invention thus reaches the ultimate in miniaturization. The atomic optoelectric devices, e.g., achieve the highest packing density. Thousands of these devices can form a 1-D linear array measuring only one micron in length. A one-square micron 2-D array can contain one million of these sensors, transistors, or bits of memories for storing information; while a cubic micron atomic IC particle contains one billion of these sensors, transistors, or bits of information.

Combining these atomic, molecular, or larger IC device with the usual robots containing wheels, gears, rods, and columns, atomic electromechanical (AEM) system can result. These AEM systems, varying in size from nanometers down to atomic sizes of about 3-20 angstroms, can find many uses in various industries.

As an example, the atomic, or molecular AEM systems may be implanted, inhaled, or passed along the body of a human, animal, or virus, bacteria, or plant objects. Upon receiving a telecommunicated signal from the outside, the AEM system is directed to move into a key position, even into a vital part or organ, such as the heart, brain, eye, kidney, stomach, liver, or bond joint, of the test object. The AEM system is directed to attach or bond to the vital part or organ; and to perform real-time computerized self-optimizing R&D experiments for studying, e.g., biomedical or biochemical actions or reaction of the test object to a specific combination of medicines. Li's self-optimizing patents cited elsewhere will be used.

The real-time sensed input data in these automatic computerized experiments may include mechanical (force, pressure), thermal (heat or phonon, temperature), electrical, chemical, and electro-optical data. These data include: light (photons), electrons, and ions. Other real-time sensed data may come from brain wave studies, NRM images, blood pressure data, skin resistance tests, acidity or alkalinity, and physicians' diagnoses on the test objects. The purpose of these real-time computerized R&D is, e.g., to determine reactions of test objects to specific drugs, chemical, virus, or physical and medical treatment; to develop new drugs or treatments by combinatorial screening; to have maximum physical and metal growth, to achieve optimal learning or training speed and accuracy; and to continuously maintain the best mental, physical, and physiological conditions for optimal sleeping, resting, reading, enjoying working, performing, and restoring or maintaining health. Telemedical diagonis, testing, experimentation, and treatment on a local, state, country, or worldwide bases are thus available, greatly lowering the cost and simplifying the record of universal health care.

Uses of the AEM systems in other industries are also numerous. An AEM system on a transportation vehicle makes it smart in achieving the optimal travel conditions under given environments of weather, road age, human constrains, rules and regulations, and vehicle conditions, for achieving the maximum passengers' comfort and minimal travel time and cost. The self-optimizing technology descried above may be used.

The AEM systems and optoelectrical devices of this invention may vary in size from 0.1 microns through 0.1 microns down to atomic sizes of about 3-4 angstroms. These systems and devices can find many uses in various industries. With many gigabits of programmed software in their memories, these nano, atomic, or molecular AEM's may even be directed to automatically enter a human or animal, even into a particular location or vital organ through feeding, implantation, or inhaling, and to pass along tiny blood or their body fluid vessels into other different parts of a human or an animal. Teletraining, telelearning, telemedical diagnosis or treatment, and implanting knowledge or skill, searching, and tracking are all now possible.

For example, modern educational experts have concluded from special experiments that unless the student's learning style is addressed, the learning can not be efficient or even relevant. Yet the student's leaning style continuously changes with his or her age, background, physical and mental conditions, time of the day or week, learning topic, procedures, materials or equipment, and environmental variables including lighting, temperature, humidity, and noise. Conventional multi-media computerized teaching systems with fixed programs cannot address the learning style, nor can it provide optimal teaching for the student on any topic, at any instant in time.

No two students are the same, at any given time instant, even on the same teaching or learning topic. Every student has a unique but unknown learning style at any time. Using one-size shoe to fit all feet may be painful. Select one teaching procedure to fit the highly variable and sensitive learning mind can even be injurious. Hence, one must run continuous, real-time multi-variables computerized, one or two-minute statistical experiments to instantly find out and set up at the optimized conditions. At any time, the teaching or learning cannot be too fast or difficult for the student to feel lost, nor too slow and boring to stay focused. By definition, the teaching and learning must be optimal. Learning is now like playing a new computer game, and the student is highly motivated to play this computer game knowing that the play is highly rewarding. Computerized comparative studies of the different students constant improve the teaching results and discover new teaching methods and principles. Under no pressure, the student is self-motivated, and would enjoy even the normally tedious leaning work.

Using Li's self-optimizing automation technology mentioned above, the new teaching system not only can efficiently teach but, more importantly, simultaneously perform automatic systematic teaching R&D continuously on each student to individually find out the instantaneous optimum conditions of all the variables for every student. In this way, the student's instantaneous leaning style is always perfectly matched.

Specifically, depending on the physical and mental conditions of the particular student, the computer automatically optimizes the multi-media, interactive equipment format, teaching materials and procedures, and various environmental variables for the student to achieve the maximum learning speed and accuracy as sensed by the computer itself. Many hardware variables and even software variables for equipment (i.e., monitor settings, display color, size, position, and font) are easily available.

A single atomic or nanometer computer with its nanosecond or picosecond speed and gigabit memory can handle many students in a whole family, class, school, district, state, or country. The simultaneous learning test results are instantly analyzed statistically to provide valuable knowledge bases and computer-generated self-optimizing teaching program for continuous improvement.

### Optimized Learning or Teaching Therefore is Always Obtained.

In telemedical treatment of patients, the superlarge memory size allows the storage of thousands or millions of different patients as to their personal, medical treatment and results, and the usage of thousands or millions of drugs and treatments with their comparative results. This is exceptionally good for unusual rare diseases, drug treatment results, and the innumerable drug-drug or drug-patient interactions no human or teams of physicians could master.

The following United States patents or application relating to solid state device of the present invention are made of record:

U.S. Patents of Shockley (U.S. Pat. No. 2,787,564), Gale (U.S. Pat. No. 2,434,894), Kellett et al (U.S. Pat. No. 3,341,754), Sibley (U.S. Pat. No. 3,326,176), and Gibbons (U.S. Pat. No. 3,563,809) on “Ion Implantation”;

Peltzer's U.S. Pat. No. 3,648,125 on “Method of Fabricating Integrated Circuits”;

Mark, L., Gardner et al, U.S. Pat. No. 5,824,175 on “Semiconductor Circuit Device Having a Trilayer Gate Isolating Dielectric”;

Li's U.S. Pat. No. 3,430,109 on “Solid-State Device with Differentially Expanded Junction Surfaces”;

Li's U.S. Pat. No. 3,585,714 on “Method for Making Solid-State Devices”;

Li's application Ser. No. 154,300, filed Jun. 18, 1971 on “Method for Making Solid-State Device”;

Li's U.S. Pat. No. 4,946,800 on “Method of Making Solid-State Device Utilizing Dielectric Isolation Grooves”;

Li's application Ser. No. 08/483,937 filed Jun. 7, 1995;

Li's U.S. Pat. No. 7,038,290 on “Integrated Circuit Device”;

Li's application Ser. No. 10/758,081 filed Jan. 20, 2004 on “Integrated Circuit Device”;

Li's U.S. Pat. No. 6,599,781 on “Method of Making Solid State Devices”;

Li's application Ser. No. 09/670,874 filed on Sep. 27, 2000 on “Semiconductor Integrated Circuit Device;

Li's U.S. Pat. No. 5,874,175 on “Ceramic Composite”;

Li's U.S. Pat. No. 6,513,025 B1 on “Self-Optimization with Interactions”;

Li's U.S. Pat. No. 6,144,954 on “Automatic Development of Computer Software”; and

Xi-wei Lin et al, Publication No. U.S. 2002/016484846 A1, Ser. No. 10/135,435 filed Apr. 9, 2002.

I hereby incorporate the above-referenced patents, and patent applications. Also, patents or papers of Shockley, Gale, Kellett et al, Sibley, Gibbons cited above are incorporated herein.

### OTHER REFERENCES

99-1451, Nov. 8, 2000, Federal Circuit Decision
223-55, 1975 PTO Board Decision
456-32, 1981 PTO Board Decision

The invention, as described above, is not to be construed as limited to the particular forms disclosed herein, since these are to be regarded as illustrative rather than restrictive.

For example, instead of silicon oxide or nitride, various electrically insulating or inert semiconductors, oxides, nitrides, intermetallic compounds, and other materials may be used to replace silicon oxide. oxynitrides, composite oxide/nitride, and high-dielectric (high-k) or low-k dielectrics for the gate, isolating region, or similar components in any solid-state device of this invention to achieve the same purpose as the gate and field layers or insulating region in MOS or CIS circuits.

It is also to be understood that the following claims are intended to cover all of the generic and specific features of the invention herein described, and all statements of the scope of the invention which, as a matter of language, might be said to fall there between.

1.-44. (canceled)

45. A commercially mass-produced [supported in U.S. Pat. No. 7,118,942; col. 4, line 59, or ('942:4/59)] miniaturized semiconductor integrated circuit (IC) containing within one cubic millimeter therein over a number of circuit components, said number being selected from the group consisting of one, five, hundred kilo, mega, gaga, and tera, comprising:
a solid substrate having a top surface; and
a solid-state material layer no more than 25 atoms thick ('942:5/25-26) and positioned on the top surface of said solid substrate ('942:FIG. 6).

46. The miniaturized semiconductor IC as in claim 45 wherein said IC is of a type selected from the group consisting of single electron device, single-hole device, single-carrier device, single-photon device, single-particle device ('942:33/36-37 and 2/54-55), atomic sensors, nanometer sensors, and molecular sensors ('942:19/31), one-dimensional IC, two-dimensional IC, and three-dimensional IC ('942:17/6-8).

47. The miniaturized semiconductor IC as in claim 45 comprising:
a solid state material layer having, at a selected portion thereof a size selected from the group consisting of a few atomic layers, a few nanometer layers, and a few molecular layer ('942: FIG. 6 and 27/30-31).

48. The miniaturized semiconductor IC as in claim 45 wherein a first selected circuit component of a doped semiconductor material is adjacent to a second circuit component of the same but intrinsic, semiconductor material thereby minimizing the thermal mismatch stresses there between to achieve a commercially acceptable yield ('942:13/29-31 and 20/62-67).

49. The miniaturized semiconductor IC as in claim 45 comprising:
a solid substrate having an electrical conductivity of one type;
a solid state material layer having an electrical conductivity of the opposite type;
at least one electronic rectifying barrier where said solid solid-state material layer positions on the top surfaces of said solid substrate; and
at least one electrically isolating groove adjoining said at least one electronic rectifying barrier to electrically isolate said multiple circuit components ('942:FIG. 6).

50. The miniaturized semiconductor IC as in claim 45, wherein:
said solid state material layer is a thin, flexible, curved, and smooth-surfaced gate layer 3-40 Angstroms thick ('942:25/63-64) and positioned between said solid substrate and said solid-state material layer;
said gate layer, said solid stare material layer, and said solid substrate all consist essentially of a single specified semiconductor material, either doped or intrinsic, so as to have essentially the same density and thermal expansion coefficients whereby the thin gate layer has no vertical micro cracks and during a subsequent dopant diffusion step no dopant can possibly fill these micro cracks to short out said solid substrate to said solid state material layer.

51. The miniaturized semiconductor IC as in claim 49 wherein:
said electrically isolating groove has a concavely rounded bottom terminating at a single groove bottom line G ('942: FIG. 3) of zero width for maximum device miniaturization; and also laterally adjoins side surfaces of said convexly rounded, electronic rectifying barrier to form a rounded and differentially surface-expanded, rectifying barrier peripheral surface;
peripheral surface expansion of said electronic rectifying barrier at said single groove bottom line being nearly infinite thereby making it difficult or impossible to short-out said rectifying barrier bottom tip by particles of rubbing contaminating metal to minimize leakage current;
any potential contaminating particle even having the exactly right shape, size, position and trajectory is likely to bounce and centrifuge out to hit the rounded rectifying barrier peripheral surface only once at a single point without completing a nearly impossible but damaging shorting path making it probably unnecessary to have the customary theatrical but uncomfortable white hat, face-masks, robes, and shoes that increase IC device cost, processing time, and processing steps to over 600; reduce productivity and even device yield due to other potential hazards to the IC; and
said single bottom line G of zero width being vertically less than 0.1 micron below said rectifying barrier to achieving maximum beneficial proximity effect of the rounded groove bottom for improving said IC device ('942: FIG. 2).

52. The miniaturized semiconductor IC as in claim 45 wherein:
said miniaturized semiconductor IC is for use as a photoelectric device designed to convert one into the other of impacting photons and an electrical entity;
said electrical entity is selected from the group consisting of electrical digital signals or energy waves; and
said photons are radiating from the group consisting of a light source or generator including laser ('942:15/18-17/53); and including:
means for allowing only impacting photon-generated electronic carriers of only one polarity type to move downward from said semiconductor layer;
said allowing means comprising an electronic rectifying barrier.

53. The miniaturized semiconductor IC as in claim 52 wherein:
said solid substrate and said solid state material layer consist essentially of a single specified material of either doped or intrinsic type and differing from each other in doping impurity contents by only several parts per million to thereby have essentially the same densities and thermal coefficients of expansion for minimizing thermal mismatch stresses and strains, whereby said IC is made environmentally resistant to heat, thermal cycling, impact, vibration, acceleration, and deceleration ('942:13/29-31 and 28/18-36).

54. The miniaturized semiconductor IC as in claim 45 wherein:
said solid state material layer is a gate layer having a rounded bottom of zero bottom width for maximum device miniaturization, and also an unusual chemical purity and mechanical strength, ('942:20/30-48);
at least a major portion of said gate layer consisting essentially of a highly purified material and having a strengthened and atomically smooth major surface ('942:23/19-24, 25/4-14, and FIG. 6); and including:
a gate lead positioned above said gate layer for electrically insulating and protecting at least a portion of said solid substrate against short-circuiting out with said gate lead;

55. The miniaturized semiconductor IC as in claim 49 wherein:
at least one of said solid substrate, said solid state material layer, and said rectifying barrier comprises a semiconductor material from the group consisting of Si atoms, Si nanoparticles, silicon molecules, Ge atoms, Ge nanoparticles, Ge molecules, Si—Ge, GaAs, GaP, InP, InSb, SiC, diamond, other III-V semiconducting compounds, and other II-VI semiconducting compounds, ferromagnetic, piezoelectric, ceramic superconductor ('942:2/47-51 and 19/1-5), and a mixture thereof:
said electronic rectifying harrier is selected from the group consisting of PN junction ('942:15/6-7), metal-oxide barrier ('942:5/36-37), metal-semiconductor barrier; oxide-semiconductor barrier ('942:5/36-37), three-semiconductor element semiconductor such as InAIP ('942:2149), heterojunction containing multiple semiconductors such as Si—Ge ('942:2/48), and other electro optically and photoelectromagnetically active signal-translating region ('942:5/36-37), and a mixture thereof; and
material for said electrically isolating groove comprises a material selected from the group consisting of air, vacuum, oxide, nitride, silicide, silicate, organic, non-organic, semiconductor, non-semiconductor, intrinsic semiconductor, a material comprising metal, metal, aluminum copper, tungsten, solid comprising metal, metal compounds, intermetallics, CVD black diamond, fluoridated silicate glass, high-k or low-k dielectric, Silk organic material from Dow Chemical, and a mixture thereof ('942:32/41-61).

56. The miniaturized semiconductor IC as in claim 45 wherein:
material of said solid state material layer comprises a compound of a chemical element selected from the group consisting of Si, Al, Cu, Hf, Zr, Ir, and a Group IVa element of the Periodic Table ('942:28/37-39);
said compound being selected from the group consisting of oxide, nitride, silicide, and silicate ('942:32/55-59).

57. The miniaturized semiconductor IC containing within one millimeter therein over a number of circuit components, said number being selected from the group consisting of two, five, hundred, kilo, mega, giga, and tera, comprising:
a solid substrate having a first polarity;
at least two solid state material bodies having a second polarity that is opposite to said first polarity and for placement on said solid substrate;
a signal-translating, electronic rectifying barrier between said solid substrate and each of said at least two solid state material bodies; and
an electrically isolating groove to electrically separate said at least two solid state material bodies;
said groove containing a material selected from the group consisting of several molecules and several nanometer ('942: FIG. 6 and 33/25-26).

58. The miniaturized semiconductor IC as in claim 57 comprising:
a miniature robot having therein a miniaturized semiconductor IC in the form of an electromagnetic/mechanical system (EMMS) having a size of no more than 10 microns (942:25/63-64, 34/49, and FIG. 6 and '634:38/59-60).
said EMMS being used in an industry selected from the group consisting of biological, biomedical, biochemical, wireless, satellite, home appliance, buildings, structures, transportation, vehicles, defense, home security, learning or training, sleeping, resting, reading enjoying working, performing health, bio-researching tele-learning, tele-medical diagnosis, tele-medical treating, knowledge or skill implanting, automation, self-optimization, search, tracking and medical, mechanical, bio-sensing, biochemical, and bio-analyzing, thermal, electrical, and electrochemical ('942:17/63-181/5 and 19/29-35); and including:
means for attaching said EMMS to and used on an object selected from the group consisting of human, animal, virus, bacteria, equipment, vehicle, servicing organization, manufacturing plant, corporation, school, and government;
means for sending a telecommunicated signal from outside of said object to said EMMS system;
means for causing said EMMY to perform, according to said received telecommunicated signal, at least one automatic computerized experiment for studying selected actions and reactions of said object to a specific combination of treatments and biomedical procedures on said object ('634:38/59-60); and
means for sensing in said at least one real-time, automatic computerized experiment input data selected from the group consisting of mechanical, thermal, electrical, chemical, financial, and electro-optical data, brain waves, nuclear magnetic images, blood pressure, skin resistance, and acidity or alkalinity of a selected body liquid ('942:19/30-35).

59. The miniaturized semiconductor IC as in claim 58 including:
storage means for storing computer software and digital information in said EMMS system;
means for receiving telecommunicated signals form outside of said object to said NMMS system; and
means for performing computerized experiments for studying selected actions or reactions of said object to a selected procedure or treatment whereby said object always operates optimally ('942:18/58-670).

60. The miniaturized semiconductor IC as in claim 58 wherein:
said object is selected from the group consisting of humans and animals; and
including means for connecting said object to said EMMS system along a fluid vessel into a selected part of said object to study light-sensitive biomedical or biochemical actions or reactions to specific medical treatment or medicine;
said connecting means being selected form the group consisting of implanting means, inhaling means, and passing along means; and
said fluid vessel being selected form the group consisting of blood vessel and other body fluid vessel ('942:19/27-35).

61. A commercially mass-produced miniaturized semiconductor IC containing within one millimeter therein over a number of circuit components, said number being selected from the group consisting of two, five, hundred, kilo, mega, giga, and tera comprising:
a solid substrate having a first polarity and a top surface;
at least a first and second semiconductor material bodies having a second polarity that is opposite to said first polarity for placement on said solid substrate;
a signal-translating, electronic rectifying barrier between said solid substrate and each of said at least two semiconductor bodies; and
an electrically isolating groove to electrically separate said at least two solid state material bodies;
said groove containing a material selected from the group consisting of several molecules and several nanometer ('942:FIG. 6 and 33/25-26).

62. The miniaturized semiconductor IC as in claim 61 comprising
a first vertical row contains at least three semiconductor bodies of one conductivity type. ('942:FIG. 6, bottom three particles of first vertical column 62); and
a second vertical row also of at least three semiconductor bodies of said one conductivity type and arranged in parallel to said first vertical row (942:FIG. 6, bottom three particles of second vertical column 63).

63. The miniaturized semiconductor IC as in claim 61 wherein:
said at least first and second semiconductor bodies form, with their respective electronic rectifying barrio; at least two photovoltaic semiconductor IC components; and including:
means for allowing photon particles to impact onto respective top surfaces of said at least two photovoltaic semiconductor IC components to produce photon-generated electron and hole pairs; and
screening means to allow only electronic carriers of one polarity to go from said solid state material layer downward into said solid substrate ('942:15/18-52);
said screening means comprising electronic rectifying barriers selected from the group consisting of PN junction ('942:15/6-7), metal-oxide barrier ('942:5/36-37), metal-semiconductor barrier, oxide-semiconductor barrier ('942:5/36-37), three-semiconductor element semiconductor such as InAlP ('942:2/49), heterojunction containing multiple semiconductors such as Ge—Si (942:2/48), and other electro optically and ptoelectromagnetically active signal-translating region ('942:5/36-37), and a mixture thereof.

64. The miniaturized semiconductor IC as in claim 45 wherein:
said IC is capable of an operating temperature selected from the group consisting of 500° C., 630° C., 800° C., and 950° C. ('942:21/50-53).
